(19) United States
(12) Patent Application Publication
(10) Pub. No.: US 2014/0377893 A1
(43) Pub. Date: Dec. 25, 2014

(54) SEMICONDUCTOR DEVICE AND MANUFACTURING METHOD THEREOF

(71) Applicant: Semiconductor Energy Laboratory Co., Ltd., Atsugi-shi (JP)

(72) Inventors: Tetsuji ISHITANI, Isehara (JP); Daisuke KUBOTA, Isehara (JP); Takeshi NISHI, Atsugi (JP)

(21) Appl. No.: 14/479,764

(22) Filed: Sep. 8, 2014

Related U.S. Application Data
(62) Division of application No. 12/641,413, filed on Dec. 18, 2009.

(30) Foreign Application Priority Data
Dec. 25, 2008 (JP) 2008-330915

(51) Int. Cl. G02F 1/1333; G02F 1/1335; G02F 1/1362; H01L 27/12; H01L 29/66

(52) U.S. Cl. CPC G02F 1/1333; H01L 27/1259; H01L 29/66969; G02F 1/136209; G02F 1/133603
USPC 438/23

(57) ABSTRACT

It is an object to provide a liquid crystal display device capable of displaying a moving image with high image quality by employing a time-division display system (also called a field-sequential system) with the use of a plurality of light-emitting diodes (hereinafter referred to as LEDs) as a backlight. Further, it is an object to provide a liquid crystal display device in which high image quality, full color display, or low power consumption is realized by adjustment of the peak luminance. After a liquid crystal layer is sealed between a pair of substrates, polymer stabilization treatment is performed with the use of UV irradiation from both above and below the pair of substrates at the same time, whereby the polymer included in the liquid crystal layer sandwiched between the pair of substrates is evenly distributed. Thus, a liquid crystal display device is manufactured.

### BACKGROUND OF THE INVENTION

1. Field of the Invention

The present invention relates to a semiconductor device having a circuit formed using a thin film transistor (hereinafter referred to as a TFT) and a manufacturing method thereof. For example, the present invention relates to an electronic device on which an electro-optical device typified by a liquid crystal display panel is mounted as a component.

In this specification, a semiconductor device refers to all types of devices which can function by utilizing semiconductor characteristics. An electro-optical device, a semiconductor circuit, and an electronic device are all included in the category of the semiconductor device.

2. Description of the Related Art

In recent years, a technique for forming a thin film transistor (TFT) by using a semiconductor thin film (with a thickness of approximately several nanometers to several hundreds of nanometers) formed over a substrate having an insulating surface has been attracting attention. The thin film transistor is widely applied to electronic devices such as ICs and electro-optical devices and is rapidly developed particularly as a switching element of an image display device.

As typically seen in a liquid crystal display device, a thin film transistor formed over a flat plate such as a glass substrate is manufactured using amorphous silicon or polycrystalline silicon.

Further, attention has been drawn to a technique by which a thin film transistor is manufactured using an oxide semiconductor and such a transistor is applied to an electronic device or an optical device. For example, Patent Document 1 and Patent Document 2 disclose a technique by which a thin film transistor is manufactured using zinc oxide or an In—Ga—Zn—O based oxide semiconductor for an oxide semiconductor film and such a transistor is used as a switching element or the like of an image display device.

Furthermore, a liquid crystal exhibiting a blue phase in a liquid crystal display device has been attracting attention. It is disclosed by Kikuchi et al. that the temperature range of the blue phase is widened by polymer stabilization treatment (see Patent Document 3), which is leading the way to practical application of the liquid crystal exhibiting a blue phase.

### REFERENCE

[Patent Document 1] Japanese Published Patent Application No. 2007-123861
[Patent Document 2] Japanese Published Patent Application No. 2007-096055
[Patent Document 3] PCT International Publication No. WO2005/090520

### SUMMARY OF THE INVENTION

In the case where a liquid crystal material exhibiting a blue phase is used for a liquid crystal layer, after the display is set in white by application of voltage from black display under the state of applying no voltage, when application of voltage is stopped again, the display might not return to black completely and leakage of light might be generated; therefore, a problem of reduction in image quality and contrast might be caused. It is an object to provide a liquid crystal display device with reduced leakage of light.

In order to increase the subframe frequency in the case of moving image display in the liquid crystal display device, switching speed of a thin film transistor that is used for writing and erasing data is preferably made higher.

Further, in the liquid crystal display device that uses a cold-cathode fluorescent lamp as a backlight, the cold-cathode fluorescent lamp is made in a lighting state even when black display is performed on the whole screen; therefore, it is difficult to realize low power consumption. In addition, since the backlight of the cold-cathode fluorescent lamp has a constant amount of light, the peak luminance does not change and it is difficult to realize high image quality in moving image display. Furthermore, in the case of using a cold-cathode fluorescent lamp as a backlight, light emitted from the backlight is white; accordingly, a color filter for full color display is provided. One pixel is divided into three sub-pixels: a sub-pixel for red, a sub-pixel for blue, and a sub-pixel for green; thus, full color display is performed. Such a method of the liquid crystal display device is called spatial color mixing, in which light of a desired color is obtained by changing the intensities of lights which pass through the sub-pixel for red, the sub-pixel for blue, and the sub-pixel for green and mixing the lights.

In view of the aforementioned situation, it is an object to provide a liquid crystal display device capable of displaying a moving image with high image quality by employing a time-division display system (also called a field-sequential system) with the use of a plurality of light-emitting diodes (hereinafter referred to as LEDs) as a backlight. Further, it is an object to provide a liquid crystal display device in which high image quality, full color display, or low power consumption is realized by adjustment of the peak luminance.

A liquid crystal material exhibiting a blue phase has a short response time of 1 millisecond or less from the state of applying no voltage to the state of applying voltage and short-time response is possible. However, when the liquid crystal is returned to the state of applying no voltage from the state of applying voltage, the alignment of the liquid crystal becomes incomplete partially.

This phenomenon is called residual birefringence. By voltage application, liquid crystal molecules are aligned in a voltage application direction and optical birefringence is caused, and when application of voltage is stopped, the alignment in part of the liquid crystal does not fully return to the alignment in the state before the voltage application; thus, birefringence remains.

One of the causes of the residual birefringence is uneven distribution of a polymer included in the liquid crystal layer between a pair of substrates.

In view of the above, after a liquid crystal layer is sealed between a pair of substrates, polymer stabilization treatment is performed with the use of UV irradiation from both above and below the pair of substrates at the same time, whereby the polymer included in the liquid crystal layer sandwiched between the pair of substrates is evenly distributed. Note that the polymer stabilization treatment is a treatment in which irradiation with ultraviolet light is performed and a reaction of an unreacted component (a low-molecular-weight component or a free radical) included in the liquid crystal layer is promoted by energy of the ultraviolet light, or a treatment in which irradiation with ultraviolet light is performed under heating and a reaction of an unreacted component (a low-molecular-weight component or a free radical) included in the liquid crystal layer is promoted by energies of the ultraviolet light and heat.

Since the UV irradiation is performed from both above and below the pair of substrates at the same time, it is preferable that a color filter is not provided between the pair of substrates and that materials which transmit ultraviolet light are used for an interlayer insulating film and the substrates.

Note that the wavelength of the ultraviolet light used in the UV irradiation is 450 nm or less and within the range of the wavelength to which the In—Ga—Zn—O based non-single-crystal film formed by a sputtering method has photosensitivity; however, since a light-blocking layer is provided, electric characteristics of the thin film transistor are not affected. Accordingly, the structure of protecting the oxide semiconductor layer of the thin film transistor from light by sandwiching the oxide semiconductor layer to be a channel formation region of the thin film transistor between a gate electrode and the light-blocking layer is effective in terms of the process.

In addition, although the ultraviolet light used in the UV irradiation is within the range of the wavelength to which amorphous silicon has photosensitivity, electric characteristics of the thin film transistor are not affected since a light-blocking layer is provided.

In this specification, a material having a transmittance of at least less than about 50%, preferably less than 20% at a wavelength of 400 nm to 450 nm is used for the light-blocking layer. For example, a metal film of chromium or titanium nitride or a black resin can be used as a material of the light-blocking layer. In the case of using a black resin for blocking light, as the light intensity is higher, the film of the black resin needs to be thicker. Therefore, in the case where the film of the black resin needs to be thin, a metal film which has a high light-blocking property and can be subjected to a fine etching process and can be thinned is preferably used.

In this manner, a liquid crystal display device which includes a liquid crystal layer exhibiting a blue phase and is suited for a field-sequential system can be realized.

A structure of an embodiment of the invention disclosed in this specification is a manufacturing method of a semiconductor device, which includes the steps of: forming, over a first light-transmitting substrate, a gate electrode, a light-blocking layer, and a thin film transistor including an oxide semiconductor layer between the gate electrode and the light-blocking layer; forming a pixel portion including a pixel electrode which is electrically connected to the thin film transistor; fixing the first light-transmitting substrate and a second light-transmitting substrate to each other with a liquid crystal layer including a photocurable resin and a photopolymerization initiator interposed therebetween; irradiating the liquid crystal layer with ultraviolet light from both above and below the first light-transmitting substrate and the second light-transmitting substrate; fixing a first polarizing plate to the first light-transmitting substrate and a second polarizing plate to the second light-transmitting substrate after irradiation of the liquid crystal layer with the ultraviolet light; and fixing a backlight portion including plural kinds of light-emitting diodes so as to overlap with the pixel portion of the first light-transmitting substrate.

In addition to the above-described structure, a second light-blocking layer may be provided for the second light-transmitting substrate in a position that overlaps with the thin film transistor. This second light-blocking layer preferably overlaps with the oxide semiconductor layer and has a larger top surface shape than the oxide semiconductor layer.

With the above-described structure, at least one of the above problems is solved.

Further, a light-blocking layer for blocking light such as outside light or ultraviolet light used for irradiation in the manufacturing process so that the light does not enter the oxide semiconductor layer provided over the first light-transmitting substrate can also be provided for the second light-transmitting substrate. Another structure of an embodiment of the invention is a manufacturing method of a semiconductor device, which includes the steps of: forming, over a first light-transmitting substrate, a gate electrode and a thin film transistor including an oxide semiconductor layer which overlaps with the gate electrode; forming a pixel portion including a pixel electrode which is electrically connected to the thin film transistor; fixing a second light-transmitting substrate provided with a light-blocking layer to the first light-transmitting substrate with a liquid crystal layer including a photocurable resin and a photopolymerization initiator interposed therebetween; irradiating the liquid crystal layer with ultraviolet light from both above and below the first light-transmitting substrate and the second light-transmitting substrate; fixing a first polarizing plate to the first light-transmitting substrate and a second polarizing plate to the second light-transmitting substrate after irradiation of the liquid crystal layer with the ultraviolet light; and fixing a backlight portion including plural kinds of light-emitting diodes so as to overlap with the pixel portion of the first light-transmitting substrate.

In the above-described structure, the light-blocking layer preferably overlaps with the oxide semiconductor layer, covers at least the oxide semiconductor layer, and has a larger top surface shape than the oxide semiconductor layer. In addition to the above-described structure, the second light-blocking layer may be provided for the first light-transmitting substrate in a position that overlaps with the thin film transistor. The second light-blocking layer provided for the first light-transmitting substrate preferably overlaps with the oxide semiconductor layer and has a larger top surface shape than the oxide semiconductor layer.

With the above-described structure, at least one of the above problems is solved.

In the case of employing a field-sequential system in which a color filter is not used, a red LED, a green LED, a blue LED, and the like are used as a backlight and high-speed driving (at least three times higher speed driving) is necessary.

Since the subframe frequency is increased in moving image display, it is preferable that a liquid crystal material exhibiting a blue phase is used as a material used for the liquid crystal layer. If the liquid crystal material exhibiting a blue phase is used, switching of color for displaying one color per field can be performed in 1/180 seconds or less, that is about 5.6 milliseconds or less. The liquid crystal material exhibiting a blue phase has a short response time of 1 msec or less and enables high-speed response, whereby the liquid crystal display device can show higher performance. The liquid crystal material exhibiting a blue phase includes a liquid crystal and a chiral agent. The chiral agent is employed to align the liquid crystal in a helical structure and to make the liquid crystal to exhibit a blue phase. For example, a liquid crystal material into which a chiral agent is mixed at 5 wt % or more may be used for the liquid crystal layer. As the liquid crystal, a thermotropic liquid crystal, a low-molecular liquid crystal, a high-molecular liquid crystal, a ferroelectric liquid crystal, an anti-ferroelectric liquid crystal, or the like is used.

The liquid crystal material is not limited to the liquid crystal material exhibiting a blue phase as long as short-time response is possible and a field-sequential driving system can be employed. For example, an optically compensated bend (OCB) mode in which liquid crystals are aligned in the bend state may be employed.

As a technique for realizing a wide viewing angle, a method is used in which a gray scale is controlled by generating an electric field that is parallel or substantially parallel (i.e., in a lateral direction) to a substrate to move liquid crystal molecules in a plane parallel to the substrate. In such a method, an electrode structure used in an in-plane switching (IPS) mode or an electrode structure used in a fringe field switching (FFS) mode can be employed.

When the subframe frequency is increased in moving image display, degradation of image quality due to motion blur caused in moving image display can be reduced by making all LEDs in a non-lighting state in a certain frame or subframe period to perform black display on the whole screen (so called black insertion).

One field is composed of a period of writing an image signal to respective pixels in a selected period and a period of storing the written image signals in a non-selected period. A TFT having an on current necessary to complete writing within the selected period is arranged in each pixel. Further, in order to keep the display state in one field period, it is preferable that leakage current in a non-selected period or storage period be as small as possible. As the TFT that satisfies these requirements, it is preferable to use a TFT which uses an oxide semiconductor typified by an In—Ga—Zn—O based oxide semiconductor for a semiconductor layer including a channel formation region.

In addition, a light-blocking layer (also referred to as a black matrix) provided over the thin film transistor has an effect of preventing variation in electric characteristics of the thin film transistor due to photosensitivity of the oxide semiconductor and stabilizing the electric characteristics. For example, an In—Ga—Zn—O based non-single-crystal film formed by a sputtering method using a target (In₂O₃:Ga₂O₃:ZnO=1:1:1 in a molar ratio) has photosensitivity to a wavelength of 450 nm or less; therefore, it is effective to provide a light-blocking layer which blocks light with a wavelength of 450 nm or less. Further, the light-blocking layer can prevent light leakage to an adjacent pixel, which enables higher contrast and higher definition display. Therefore, by provision of the light-blocking layer, higher definition and higher reliability of the liquid crystal display device can be achieved.

Furthermore, the LEDs are not limited to the red LED, the green LED, and the blue LED, and a cyan LED, a magenta LED, a yellow LED, or a white LED can be used. Note that LEDs have a short response time of several tens of nanoseconds to several hundreds of nanoseconds, which is sufficiently shorter than that of liquid crystal materials.

Moreover, the backlight is not limited to LEDs, and an inorganic EL element or an organic EL element can be used if it is a point light source.

When plural kinds of light-emitting diodes are used as a backlight, lighting time or luminance of respective LEDs can be adjusted. For adjustment of the lighting time or luminance of the LEDs, a driver circuit for the LEDs is provided.

Further, it is preferable that at least one LED be provided in each of a plurality of regions into which a display area of the liquid crystal display device is divided, and an LED control circuit which drives the LEDs per region in accordance with respective video signals be provided. By driving the LEDs per region, the luminance can be adjusted locally in the display area. For example, selective lighting of LEDs is possible in such a manner that a first region which needs lighting of an LED is made in a lighting state and a second region which does not need lighting of an LED is made in a non-lighting state. Thus, lower power consumption of the liquid crystal display device can be realized, although depending on the display image.

By independently controlling the LEDs per emission color, the color temperature of the display screen can be adjusted in accordance with the external lighting environment; accordingly, a liquid crystal display device with high visibility can be provided. Further, if an optical sensor which detects external light is provided for the liquid crystal display device, luminance of the LEDs for respective colors can be automatically adjusted in accordance with the external lighting environment.

In addition, a normally black mode is set for the liquid crystal display device that uses a field-sequential system. A liquid crystal display device which operates in a normally black mode displays black on its screen under the state of applying no voltage to the liquid crystal layer. When voltage is applied to the liquid crystal layer, light from the backlight (light emitted from the LEDs) is transmitted and color of the emitted light is displayed on the screen.

Further, an optical sheet such as a prism or a light diffusion plate may be provided between the backlight and the pair of substrates between which the liquid crystal layer is sandwiched.

In this specification, a light-transmitting substrate refers to a substrate having a transmittance of visible light of 80% to 100%.

A term indicating a direction such as “on”, “over”, “under”, “below”, “side”, “horizontal”, or “perpendicular” in this specification is based on the assumption that a device is provided over a substrate surface.

A field-sequential liquid crystal display device capable of moving image display with higher image quality can be provided.

### BRIEF DESCRIPTION OF THE DRAWINGS

In the accompanying drawings:

FIGS. 1A to 1C are cross-sectional views illustrating an example of a manufacturing process of a liquid crystal display device;

FIG. 2 is an exploded perspective view illustrating an example of a liquid crystal display module;

FIGS. 3A and 3B are a top view and a cross-sectional view, respectively, illustrating an example of a pixel;

FIGS. 4A and 4B are a top view and a cross-sectional view, respectively, illustrating an example of a pixel;

FIGS. 5A1, 5A2, and 5B illustrate liquid crystal display devices;

FIG. 6 illustrates a liquid crystal display module;

FIG. 7 is an external view illustrating an example of a television set;

FIGS. 8A and 8B are external views illustrating examples of a game machine; and

FIGS. 9A and 9B are external views illustrating examples of a mobile phone.

### DETAILED DESCRIPTION OF THE INVENTION

Embodiments of the present invention are hereinafter described.

### Embodiment 1

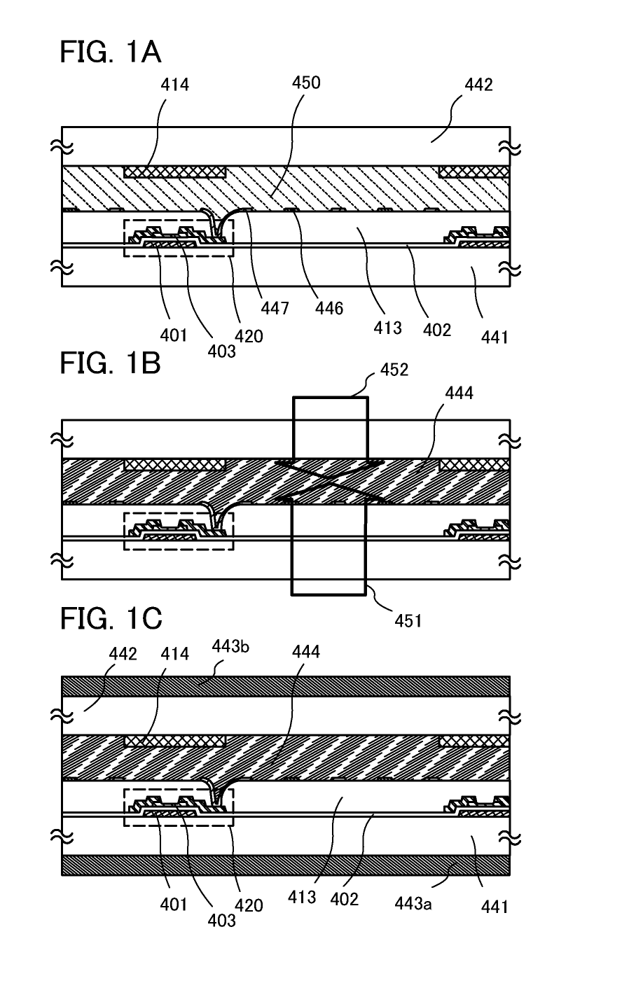

Here, a manufacturing example of a liquid crystal display device using a field-sequential system will be described below with reference to FIGS. 1A to 1C.

First, a thin film transistor (TFT) 420 that is to be a switching element is formed over a first light-transmitting substrate 441. A glass substrate is used as the first light-transmitting substrate 441. Note that a base insulating film serving as a barrier film may be provided over the first light-transmitting substrate 441. In addition, an example of using a semiconductor layer 403 for forming a channel formation region in the thin film transistor 420 will be described here.

A gate electrode layer 401 is formed over the first light-transmitting substrate 441, a gate insulating layer 402 that covers the gate electrode layer 401 is formed, and then the semiconductor layer 403 that overlaps with the gate electrode is formed over the gate insulating film 402. A material of the gate electrode layer 401 is not limited as long as it forms a light-blocking conductive film and may be an element selected from aluminum (Al), copper (Cu), titanium (Ti), tantalum (Ta), tungsten (W), molybdenum (Mo), chromium (Cr), neodymium (Nd), or scandium (Sc) or an alloy containing the above-described element. The gate electrode layer 401 is not limited to a single layer containing the above-described element and may have two or more layers. As a material of the gate insulating layer 402, a light-transmitting inorganic material (silicon oxide, silicon nitride, silicon oxynitride, silicon nitride oxide, or the like) can be used, and the gate insulating layer 402 may have a single-layer structure or a stacked structure including any of these materials. The gate electrode and the gate insulating film can be formed by a sputtering method or a vapor deposition method such as a plasma CVD method or a thermal CVD method.

The semiconductor layer 403 is formed by patterning a thin film which is expressed by InMO₃(ZnO)ₘ (m>0, m is not a natural number). Note that M represents one or more of metal elements selected from Ga, Fe, Ni, Mn, and Co. As well as the case where only Ga is contained as M, there is a case where Ga and any of the above metal elements except Ga, for example, Ga and Ni or Ga and Fe are contained as M. Moreover, in the oxide semiconductor, in some cases, a transition metal element such as Fe or Ni or an oxide of the transition metal is contained as an impurity element in addition to the metal element contained as M. In this specification, this thin film is also referred to as an In—Ga—Zn—O based non-single-crystal film. The oxide semiconductor layer is formed as follows: film deposition is performed using an oxide semiconductor target including In, Ga, and Zn (In₂O₃:Ga₂O₃:ZnO=1:1:1), under a condition in which the distance between the substrate and the target is 170 mm, the pressure is 0.4 Pa, and the direct-current (DC) power source is 0.5 kW, in an argon atmosphere containing oxygen, and a resist mask is formed and the deposited film is selectively etched off to remove an unnecessary portion thereof. Note that it is preferable to use a pulsed direct-current (DC) power source because dust can be reduced and thickness distribution can be evened. The thickness of the oxide semiconductor film is set at 5 nm to 200 nm. In this embodiment, the thickness of the oxide semiconductor film is 100 nm.

Next, after forming a conductive film that covers the oxide semiconductor layer, the conductive film is patterned to form a source electrode layer and a drain electrode layer. As a material of the conductive film, there are an element selected from Al, Cr, Ta, Ti, Mo, and W, an alloy containing any of the above-described elements as its component, an alloy containing a combination of any of the above-described elements, and the like. If heat treatment at 200° C. to 600° C. is performed later, it is preferable that the conductive film include titanium (Ti), tantalum (Ta), tungsten (W), molybdenum (Mo), chromium (Cr), neodymium (Nd), scandium (Sc), or the like in order to have heat resistance against the heat treatment.

In etching for forming the source electrode layer and the drain electrode layer, the exposed region of the oxide semiconductor film might be partially etched depending on the material used for the conductive film; in such a case, the region that does not overlap with the source electrode layer or the drain electrode layer is thinner than the region that overlaps with the source electrode layer or the drain electrode layer in the oxide semiconductor film.

Next, heat treatment is preferably performed at 200° C. to 600° C., typically, 300° C. to 500° C. In this case, thermal treatment is performed in a furnace at 350° C. for an hour in an air atmosphere. Through this heat treatment, rearrangement at the atomic level occurs in the In—Ga—Zn—O based non-single-crystal film. Because distortion that interrupts carrier transfer is reduced by this heat treatment, this heat treatment (including optical annealing) is important. Note that there is no particular limitation on the timing of the heat treatment as long as it is performed after formation of the In—Ga—Zn—O based non-single-crystal film, and for example, the heat treatment may be performed after formation of a pixel electrode.

Next, an interlayer insulating film 413 is formed. As a material of the interlayer insulating film 413, a light-transmitting inorganic material (silicon oxide, silicon nitride, silicon oxynitride, silicon nitride oxide, or the like) or a light-transmitting resin material (polyimide, acrylic, benzocyclobutene, polyamide, epoxy, siloxane-based resin, or the like) can be used, and the interlayer insulating film 413 may have a single-layer structure or a stacked structure including any of these materials. Note that a siloxane-based resin is a resin formed using a siloxane-based material as a starting material and having the bond of Si—O—Si. A siloxane-based resin may include, as a substituent, an organic group (e.g., an alkyl group or an aryl group) or a fluoro group. The organic group may include a fluoro group.

Next, a contact hole reaching the source electrode layer or the drain electrode layer is formed in the interlayer insulating film 413, and then a first electrode layer 447 and a second electrode layer 446 are formed over the interlayer insulating film 413 as a pixel electrode layer and a common electrode layer, respectively. The first electrode layer 447 and the second electrode layer 446 are preferably formed using a transparent conductive film. The second electrode layer 446 is also called a common electrode and is fixed at a predetermined potential such as GND or 0V, for example. Here, an IPS-mode liquid crystal display device is exemplified. Pixel electrodes arranged in a matrix are driven with thin film transistors, so that a display pattern is formed on a screen. Specifically, when voltage is applied between a selected pixel electrode and a common electrode that corresponds to the selected pixel electrode, optical modulation of a liquid crystal layer arranged between the pixel electrode and the common electrode is performed, and this optical modulation is recognized as a display pattern by observers.

Through the above-described process, the first electrode layer 447 and the second electrode layer 446 are arranged in a matrix so as to correspond to respective pixels and a pixel portion is formed. Thus, one of the substrates for manufacturing an active-matrix display device can be obtained. In this specification, such a substrate is referred to as an active matrix substrate for convenience.

Next, the other substrate for manufacturing the active-matrix display device, that is, a second light-transmitting substrate 442 that is a counter substrate is prepared. As the second light-transmitting substrate 442, a glass substrate is used. A light-blocking layer 414 serving as a black matrix is provided on the second light-transmitting substrate 442. The first light-transmitting substrate 441 and the second light-transmitting substrate 442 are fixed in the state that a surface of the second light-transmitting substrate 442, which is provided with the light-blocking layer 414, and a surface of the first light-transmitting substrate 441, which is provided with the thin film transistor 420, face each other, and a first liquid crystal layer 450 is provided between the substrates. The cross-sectional view in this state corresponds to FIG. 1A.

The distance between the first light-transmitting substrate 441 and the second light-transmitting substrate 442 is preferably kept constant by using a filler included in a sealant that is used to fix the substrates or a distance-keeping agent (e.g., a columnar spacer or a spherical spacer). The first liquid crystal layer 450 is provided between the substrates by an injection method in which a liquid crystal is injected by a capillary phenomenon after attachment between the first light-transmitting substrate 441 and the second light-transmitting substrate 442 or a dispenser method (a dropping method).

The first liquid crystal layer 450 is a mixture which includes a liquid crystal whose dielectric constant anisotropy is positive, a chiral agent, a photocurable resin, and a polymerization initiator. In this embodiment, a mixture of JC-1041XX (produced by Chisso Corporation) and 4-cyano-4′-pentylbiphenyl is used as the liquid crystal material. ZLI-4572 (produced by Merck Ltd.) is used as the chiral agent. As the photocurable resin, 2-ethylhexyl acrylate and RM257 (produced by Merck Ltd.) are used. As the photopolymerization initiator, 2,2-dimethoxy-2-phenylacetophenone is used.

The chiral agent is employed to align the liquid crystal in a helical structure and to make the liquid crystal to exhibit a blue phase. As the chiral agent, a material having a high compatibility with a liquid crystal and a strong twisting power is used. Either one of two enantiomers, R and S, is used, and a racemic mixture in which R and S are mixed at 50:50 is not used. For example, a liquid crystal material into which a chiral agent is mixed at 5 wt % or more may be used for the liquid crystal layer.

As the liquid crystal whose dielectric constant anisotropy is positive, a thermotropic liquid crystal, a low-molecular liquid crystal, a high-molecular liquid crystal, a ferroelectric liquid crystal, an anti-ferroelectric liquid crystal, or the like is used. These liquid crystal materials exhibit a cholesteric phase, a cholesteric blue phase, a smectic phase, a smectic blue phase, a cubic phase, a chiral nematic phase, an isotropic phase, or the like depending on conditions.

A cholesteric blue phase and a smectic blue phase, which are blue phases, are seen in a liquid crystal material having a cholesteric phase or a smectic phase with a relatively short helical pitch of less than or equal to 500 nm. The alignment of the liquid crystal material has a double twist structure. Having the order of less than or equal to an optical wavelength, the liquid crystal material is transparent, and optical modulation action is generated through a change in alignment order by voltage application. A blue phase is optically isotropic and thus has no viewing angle dependence. Thus, an alignment film is not necessarily formed; therefore, display image quality can be improved and cost can be reduced. In addition, since rubbing treatment on an alignment film is unnecessary, electrostatic discharge damage caused by the rubbing treatment can be prevented and defects and damage of the liquid crystal display device can be reduced in the manufacturing process. Thus, productivity of the liquid crystal display device can be increased. A thin film transistor that uses an oxide semiconductor layer particularly has a possibility that electric characteristics of the thin film transistor may fluctuate significantly by the influence of static electricity and deviate from the designed range. Therefore, it is more effective to use a blue phase liquid crystal material for a liquid crystal display device including a thin film transistor that uses an oxide semiconductor layer.

The blue phase appears only within a narrow temperature range; therefore, a photocurable resin and a photopolymerization initiator are added to a liquid crystal material and polymer stabilization treatment is performed in order to widen the temperature range. The photocurable resin may be a monofunctional monomer such as acrylate or methacrylate; a polyfunctional monomer such as diacrylate, triacrylate, dimethacrylate, or trimethacrylate; or a mixture thereof. For example, 2-ethylhexyl acrylate, RM257 (produced by Merck Ltd., Japan), or trimethylolpropane triacrylate can be given. Further, the photocurable resin may have liquid crystallinity, non-liquid crystallinity, or both of them. A resin which is cured with light having a wavelength with which the photopolymerization initiator to be used is reacted may be selected as the photocurable resin, and an ultraviolet curable resin (a UV curable resin) is used in this embodiment.

As the photopolymerization initiator, a radical polymerization initiator which generates radicals by light irradiation, an acid generator which generates an acid by light irradiation, or a base generator which generates a base by light irradiation may be used.

The polymer stabilization treatment is performed in such a manner that a liquid crystal material including a liquid crystal, a chiral agent, a photocurable resin, and a photopolymerization initiator is irradiated with light having a wavelength with which the photocurable resin and the photopolymerization initiator are reacted. This polymer stabilization treatment may be performed by irradiating a liquid crystal material in the state of exhibiting an isotropic phase with light or by irradiating a liquid crystal material in the state of exhibiting a blue phase with light under the control of the temperature.

Here, after heating the first liquid crystal layer 450 to the isotropic phase, the temperature of the liquid crystal layer 450 is decreased so that the phase changes to the blue phase, and then, while the temperature is kept at the temperature at which the blue phase is exhibited, UV irradiation is performed from both above and below the pair of substrates at the same time as illustrated in FIG. 1B in order to reduce generation of residual birefringence. If the UV irradiation is performed from only one substrate side, a polymer is unevenly distributed to an area close to the UV irradiation direction and residual birefringence might be caused. It is preferable that the amount of first ultraviolet light 451 which passes through the first light-transmitting substrate 441 and the amount of second ultraviolet light 452 which passes through the second light-transmitting substrate 442 be almost the same. The first ultraviolet light 451 which passes through the first light-transmitting substrate 441 is blocked by a region in which the thin film transistor 420 is formed, and the second ultraviolet light 452 which passes through the second light-transmitting substrate 442 is blocked by a region in which the light-blocking layer 414 is formed. Accordingly, a second liquid crystal layer 444 which overlaps with a pixel opening portion that contributes to display in the pixel portion can be exposed to almost the same amount of ultraviolet light from above and below. In order to expose the liquid crystal layer 444 to almost the same amount of ultraviolet light from above and below, it is effective that a first light-transmitting region in the first light-transmitting substrate 441 (a region other than the region provided with a metal wiring and a metal electrode) and a second light-transmitting region in the second light-transmitting substrate 442 (a region other than the region provided with the light-blocking layer 414) are almost the same.

Since the first light-transmitting substrate 441 is provided with the gate insulating layer 402 and the interlayer insulating film 413 unlike the second light-transmitting substrate 442, a difference in the amount of ultraviolet light might occur due to light absorption, refraction at a film interface, reflection at a film interface, or the like depending on the materials of the gate insulating layer 402 and the interlayer insulating film 413 even if the materials have a light-transmitting property. Therefore, in the case where a difference in the amount of light might occur, the amount of light from a light source of the first ultraviolet light 451 and a light source of the second ultraviolet light 452 may be adjusted, or the second light-transmitting substrate 442 may be provided with films equivalent to the gate insulating layer 402 and the interlayer insulating film 413 to adjust the amount of light.

By the polymer stabilization treatment in which UV irradiation is performed from both above and below the pair of substrates at the same time as described above, the polymer included in the second liquid crystal layer 444 sandwiched between the pair of substrates can be distributed evenly. By this polymer stabilization treatment, residual birefringence is not caused after voltage application; accordingly, the same black display as before the voltage application can be obtained and leakage of light can be reduced. Therefore, a polymer-stabilized blue-phase display element with high quality can be manufactured.

Further, since the gate electrode layer 401 blocks the first ultraviolet light 451 and the light-blocking layer 414 blocks the second ultraviolet light 452, the semiconductor layer 403 is not exposed to UV irradiation and variation in electric characteristics of the thin film transistor can be prevented.

Next, a first polarizing plate 443a is provided on the outer surface side, which is not adjacent to the liquid crystal layer, of the first light-transmitting substrate (the substrate provided with the pixel electrode). A second polarizing plate 443b is provided on the outer surface side, which is not adjacent to the liquid crystal layer, of the second light-transmitting substrate (the counter substrate). The cross-sectional view in this state corresponds to FIG. 1C. The object in the state illustrated in FIG. 1C, which includes a pair of substrates provided with two polarizing plates, is called a liquid crystal panel.

In the case of manufacturing a plurality of liquid crystal display devices using a large-sized substrate (a so-called multiple panel method), a division step can be performed before the polymer stabilization treatment or before provision of the polarizing plates. In consideration of the influence of the division step on the liquid crystal layer (such as alignment disorder due to force applied in the division step), it is preferable that the division step be performed after the attachment between the first substrate and the second substrate and before the polymer stabilization treatment.

Last, a backlight portion is fixed to the liquid crystal panel.

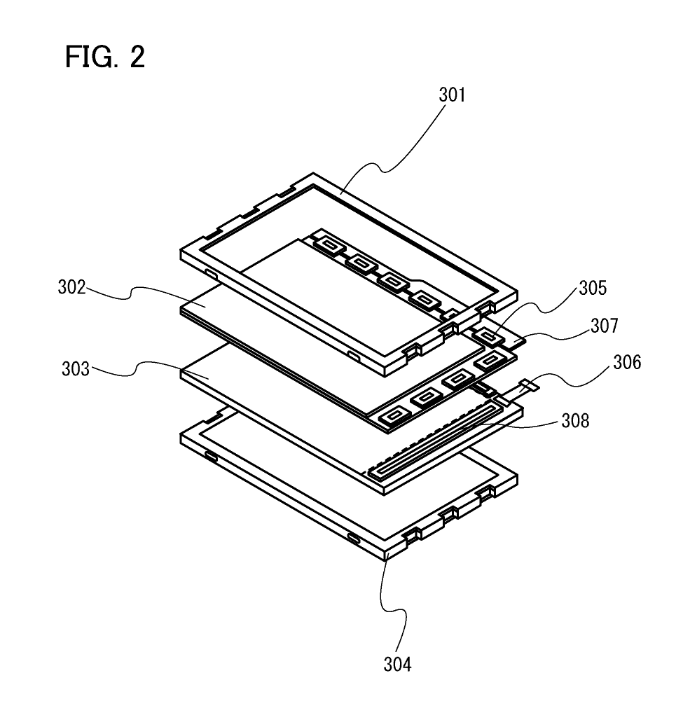

FIG. 2 is an explored perspective view of the liquid crystal module in which LEDs are used in a backlight portion. In a liquid crystal panel 302, a plurality of driver ICs 305 are provided over an element substrate, and an FPC 307 that is electrically connected to a terminal provided over the element substrate is also provided.

A backlight portion 303 is disposed under the liquid crystal panel 302.

A first housing 301 and a second housing 304 are disposed so that the liquid crystal panel 302 and the backlight portion 303 are sandwiched therebetween, and the housings are bonded to each other at their peripheral portions. Here, a window of the first housing 301 is to be a display surface of the liquid crystal module.

Many kinds of LEDs (light-emitting diodes) are used in the backlight portion 303, and the luminance of each LED is adjustable with an LED control circuit 308. Current is supplied through a connection code 306. The LEDs are individually made to emit light by the LED control circuit 308; thus, a field-sequential liquid crystal display device can be realized.

Further, at least one LED is provided in each of a plurality of regions into which a display area of the liquid crystal display device is divided, and the LEDs are driven per region in accordance with respective video signals by the LED control circuit. By driving the LEDs per region, the luminance can be adjusted locally in the display area. For example, selective lighting of LEDs is possible in such a manner that a first region which needs lighting of an LED is made in a lighting state and a second region which does not need lighting of an LED is made in a non-lighting state. Thus, lower power consumption of the liquid crystal display device can be realized, though depending on the display image.

In addition, either an inorganic material or an organic material may be used as a light-emitting material of the LEDs.

High-speed driving (at least three times higher speed driving) is necessary in field-sequential liquid crystal display devices. In this embodiment, high image quality of moving image display is realized by using a liquid crystal layer exhibiting a blue phase with a sufficiently short response time and a thin film transistor that uses an In—Ga—Zn—O based oxide semiconductor as a switching element.

### Embodiment 2

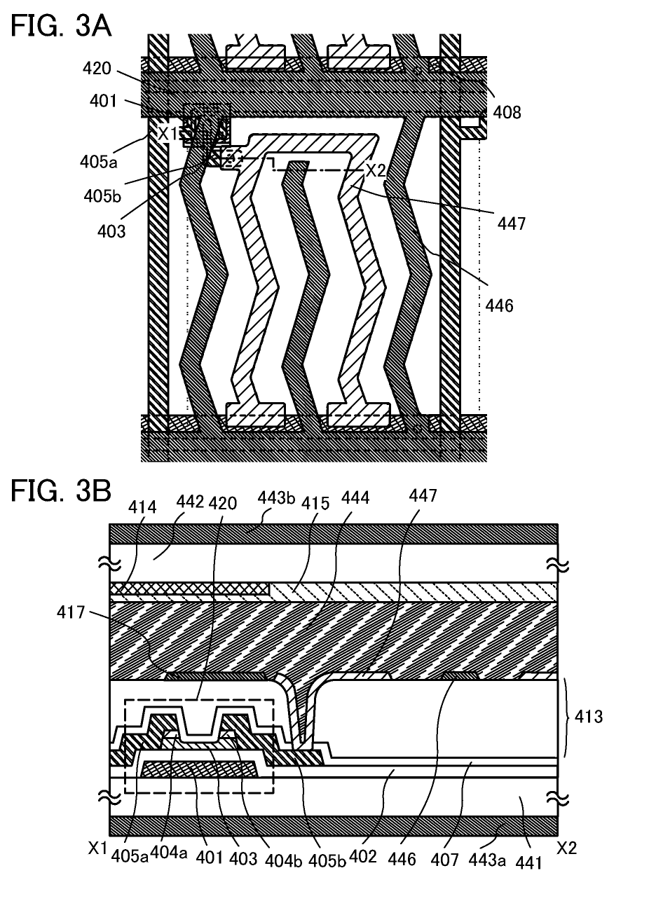

A liquid crystal display device will be described with reference to FIGS. 3A and 3B.

FIG. 3A is a plan view of a liquid crystal display device illustrating one pixel. FIG. 3B is a cross-sectional view taken along line X1-X2 in FIG. 3A.

In FIG. 3A, a plurality of source wiring layers (including a wiring layer 405a) are provided in parallel to each other (extended in a vertical direction in the drawing) and apart from each other. A plurality of gate wiring layers (including a gate electrode layer 401) are provided apart from each other and extend in a direction generally perpendicular to the source wiring layers (a horizontal direction in the drawing). Common wiring layers 408 are provided adjacent to the plurality of gate wiring layers and extend in a direction generally parallel to the gate wiring layers, that is, in a direction generally perpendicular to the source wiring layers (a horizontal direction in the drawing). Roughly rectangular spaces are surrounded by the source wiring layers, the common wiring layers 408, and the gate wiring layers, and a pixel electrode layer and a common wiring layer of a liquid crystal display device are provided in these spaces. A thin film transistor 420 for driving the pixel electrode layer is provided at the upper left corner in the drawing. A plurality of pixel electrode layers and thin film transistors are provided in matrix.

In the liquid crystal display device of FIGS. 3A and 3B, a first electrode layer 447 electrically connected to the thin film transistor 420 serves as a pixel electrode layer and a second electrode layer 446 electrically connected to the common wiring layer 408 serves as a common electrode layer. Note that a capacitor is formed by the first electrode layer and the common wiring layer.

A method in which the gray scale is controlled by generating an electric field generally parallel (i.e., in a lateral direction) to a substrate to move liquid crystal molecules in a plane parallel to the substrate can be used. For such a method, an electrode structure used in an IPS mode as illustrated in FIGS. 3A and 3B can be employed.

In a lateral electric field mode such as an IPS mode, a first electrode layer (e.g., a pixel electrode layer with which voltage is controlled per pixel) and a second electrode layer (e.g., a common electrode layer with which common voltage is applied to all pixels), which have an opening pattern, are located below a liquid crystal layer. Therefore, the first electrode layer 447 and the second electrode layer 446, one of which is a pixel electrode layer and the other of which is a common electrode layer, are formed over a first light-transmitting substrate 441, and at least one of the first electrode layer and the second electrode layer is formed over an interlayer film. The first electrode layer 447 and the second electrode layer 446 have not a plane shape but various opening patterns including a bent portion or a branching comb-shaped portion. The first electrode layer 447 and the second electrode layer 446 are arranged so as not to have the same shape and overlap with each other, in order to generate an electric field therebetween.

The top surface shape of the first electrode layer 447 and the second electrode layer 446 is not limited to the structure illustrated in FIGS. 3A and 3B and may be a wavelike shape with curves, a shape with concentric circular openings, or a comb shape in which the electrodes are engaged with each other.

By application of an electric field between the pixel electrode layer and the common electrode layer, a liquid crystal is controlled. An electric field in a lateral direction is applied to the liquid crystal, so that liquid crystal molecules can be controlled using the electric field. That is, the liquid crystal molecules oriented parallel to the substrate can be controlled in a direction parallel to the substrate; accordingly, the viewing angle can be widened.

Part of the second electrode layer 446 is formed over an interlayer insulating film 413 and serves as a light-blocking layer 417 which overlaps with the thin film transistor 420 at least partially. The light-blocking layer 417 which overlaps with the thin film transistor 420 may have the same potential as the second electrode layer 446 or may be in a floating state without electrical connection to the second electrode layer 446.

The thin film transistor 420 is an inverted staggered thin film transistor and includes, over the first light-transmitting substrate 441 having an insulating surface, the gate electrode layer 401, a gate insulating layer 402, a semiconductor layer 403, n⁺ layers 404a and 404b serving as a source region and a drain region, and wiring layers 405a and 405b serving as a source electrode layer and a drain electrode layer.

An insulating film 407 is provided in contact with the semiconductor layer 403 so as to cover the thin film transistor 420. An interlayer insulating film 413 is provided over the insulating film 407, and the first electrode layer 447 and the second electrode layer 446 are formed over the interlayer insulating film 413.

In the interlayer insulating film 413 of the liquid crystal display device of FIGS. 3A and 3B, a light-transmitting resin layer is used as an insulating film which transmits visible light.

The formation method of the interlayer insulating film 413 (the light-transmitting resin layer) is not particularly limited, and the following method can be employed in accordance with the material: spin coating, dip coating, spray coating, droplet discharging (e.g., ink jetting, screen printing, or offset printing), doctor knife, roll coating, curtain coating, knife coating, or the like.

A liquid crystal layer 444 is provided over the first electrode layer 447 and the second electrode layer 446 and sealed with a second light-transmitting substrate 442 which is a counter substrate.

A light-blocking layer 414 is further provided on the second light-transmitting substrate 442 side.

The light-blocking layer 414 is formed on the liquid crystal layer 444 side of the second light-transmitting substrate 442 and an insulating layer 415 is formed as a planarization film. The light-blocking layer 414 is preferably formed in a region corresponding to the thin film transistor 420 with the liquid crystal layer 444 (a region which overlaps with a semiconductor layer of the thin film transistor) interposed therebetween. The first light-transmitting substrate 441 and the second light-transmitting substrate 442 are firmly attached to each other with the liquid crystal layer 444 interposed therebetween so that the light-blocking layer 414 is positioned to cover at least the semiconductor layer 403 of the thin film transistor 420.

The light-blocking layer 414 is formed using a light-blocking material that reflects or absorbs light. For example, a black organic resin can be used, which can be formed by mixing a black resin of a pigment material, carbon black, titanium black, or the like into a resin material such as photosensitive or non-photosensitive polyimide. In the case of using a black resin, the thickness of the light-blocking layer 414 is set at 0.5 μm to 2 μm. Alternatively, a light-blocking metal film can be used, which may be formed using chromium, molybdenum, nickel, titanium, cobalt, copper, tungsten, aluminum, or the like, for example.

The formation method of the light-blocking layer 414 is not particularly limited, and a dry method such as vapor deposition, sputtering, CVD, or the like or a wet method such as spin coating, dip coating, spray coating, droplet discharging (e.g., ink jetting, screen printing, or offset printing), or the like may be used in accordance with the material. If needed, an etching method (dry etching or wet etching) may be employed to form a desired pattern.

The insulating layer 415 may be formed using an organic resin or the like such as acrylic or polyimide by a coating method such as spin coating or various printing methods.

When the light-blocking layer 414 is further provided on the counter substrate side in this manner, contrast can be increased and the thin film transistor can be stabilized more. The light-blocking layer 414 can block incident light on the semiconductor layer 403 of the thin film transistor 420; accordingly, electric characteristics of the thin film transistor 420 can be prevented from being varied due to photosensitivity of the oxide semiconductor and can be stabilized more. Further, the light-blocking layer 414 can prevent light leakage to an adjacent pixel, which enables higher contrast and higher definition display. Therefore, high definition and high reliability of the liquid crystal display device can be achieved.

The first light-transmitting substrate 441 and the second light-transmitting substrate 442 are light-transmitting substrates and are provided with a polarizing plate 443a and a polarizing plate 443b respectively on their outer sides (the sides opposite from the liquid crystal layer 444).

The first electrode layer 447 and the second electrode layer 446 can be formed using a light-transmitting conductive material such as indium oxide containing tungsten oxide, indium zinc oxide containing tungsten oxide, indium oxide containing titanium oxide, indium tin oxide containing titanium oxide, indium tin oxide (hereinafter referred to as ITO), indium zinc oxide, or indium tin oxide to which silicon oxide is added.

A conductive composition containing a conductive high molecule (also referred to as a conductive polymer) can be used to form the first electrode layer 447 and the second electrode layer 446. The pixel electrode formed using the conductive composition preferably has a sheet resistance of 10000 ohms per square or less and a transmittance of 70% or more at a wavelength of 550 nm. Furthermore, the resistivity of the conductive high molecule contained in the conductive composition is preferably 0.1 Ω·cm or less.

As the conductive high molecule, a so-called π-electron conjugated conductive polymer can be used. For example, it is possible to use polyaniline or a derivative thereof, polypyrrole or a derivative thereof, polythiophene or a derivative thereof, or a copolymer of two or more kinds of them.

An insulating film serving as a base film may be provided between the first light-transmitting substrate 441 and the gate electrode layer 401. The base film functions to prevent diffusion of an impurity element from the first light-transmitting substrate 441 and can be formed using one film or stacked films selected from a silicon nitride film, a silicon oxide film, a silicon nitride oxide film, and a silicon oxynitride film. The gate electrode layer 401 can be formed to have a single-layer structure or a stacked structure using a metal material such as molybdenum, titanium, chromium, tantalum, tungsten, aluminum, copper, neodymium, or scandium or an alloy material which contains any of these materials as its main component. By using a light-blocking conductive film as the gate electrode layer 401, light from a light-emitting diode of a backlight (light that comes in from the first light-transmitting substrate 441 side and is emitted through the second light-transmitting substrate 442) can be prevented from entering the semiconductor layer 403.

For example, as a two-layer structure of the gate electrode layer 401, the following structures are preferable: a two-layer structure of an aluminum layer and a molybdenum layer stacked thereover, a two-layer structure of a copper layer and a molybdenum layer stacked thereover, a two-layer structure of a copper layer and a titanium nitride layer or a tantalum nitride layer stacked thereover, and a two-layer structure of a titanium nitride layer and a molybdenum layer. As a three-layer structure, a stack of a tungsten layer or a tungsten nitride layer, a layer of an alloy of aluminum and silicon or an alloy of aluminum and titanium, and a titanium nitride layer or a titanium layer is preferable.

The gate insulating layer 402 can be formed to have a single-layer structure or a stacked structure using a silicon oxide layer, a silicon nitride layer, a silicon oxynitride layer, or a silicon nitride oxide layer by a plasma CVD method, a sputtering method, or the like. Alternatively, the gate insulating layer 402 can be formed using a silicon oxide layer by a CVD method using an organosilane gas. As the organosilane gas, a silicon-containing compound such as tetraethoxysilane (TEOS: chemical formula, Si(OC₂H₅)₄), tetramethylsilane (TMS: chemical formula, Si(CH₃)₄), tetramethylcyclotetrasiloxane (TMCTS), octamethylcyclotetrasiloxane (OMCTS), hexamethyldisilazane (HMDS), triethoxysilane (SiH(OC₂H₅)₃), or trisdimethylaminosilane (SiH(N(CH₃)₂)₃) can be used.

It is preferable that reverse sputtering in which an argon gas is introduced to generate plasma be performed before the formation of the oxide semiconductor film used as the semiconductor layer 403 in order to remove dust attached to a surface of the gate insulating layer. Note that instead of an argon atmosphere, a nitrogen atmosphere, a helium atmosphere, or the like may be used. Alternatively, an argon atmosphere to which oxygen, N₂O, or the like is added may be used. Further alternatively, an argon atmosphere to which Cl₂, CF₄, or the like is added may be used.

The semiconductor layer 403 and the n⁺ layers 404a and 404b serving as a source region and a drain region can be formed using an In—Ga—Zn—O based non-single-crystal film. The n⁺ layers 404a and 404b are oxide semiconductor layers having a resistance lower than the semiconductor layer 403. For example, the n⁺ layers 404a and 404b have n-type conductivity and an activation energy (ΔE) of 0.01 eV to 0.1 eV inclusive. The n⁺ layers 404a and 404b are In—Ga—Zn—O based non-single-crystal films and include at least an amorphous component. The n⁺ layers 404a and 404b may include crystal grains (nanocrystals) in an amorphous structure. These crystal grains (nanocrystals) in the n⁺ layers 404a and 404b each have a diameter of 1 nm to 10 nm, typically about 2 nm to 4 nm.

By the provision of the n⁺ layers 404a and 404b, the wiring layers 405a and 405b which are metal layers can have a good junction with the semiconductor layer 403 which is an oxide semiconductor layer, so that stable operation can be realized in terms of heat in comparison with a Schottky junction. In addition, willing provision of the n⁺ layer is effective in supplying carriers to the channel (on the source side), stably absorbing carriers from the channel (on the drain side), or preventing a resistance component from being formed at an interface between the wiring layer and the semiconductor layer. Moreover, since resistance is reduced, good mobility can be ensured even with a high drain voltage.

The first In—Ga—Zn—O based non-single-crystal film used as the semiconductor layer 403 is formed under deposition conditions different from those for the second In—Ga—Zn—O based non-single-crystal film which is used as the n⁺ layers 404a and 404b. For example, the first In—Ga—Zn—O based non-single-crystal film is formed under conditions where the ratio of an oxygen gas flow rate to argon gas flow rate is higher than the ratio of an oxygen gas flow rate to an argon gas flow rate under the deposition conditions for the second In—Ga—Zn—O based non-single-crystal film. Specifically, the second In—Ga—Zn—O based non-single-crystal film is formed in a rare gas (e.g., argon or helium) atmosphere (or an atmosphere, less than or equal to 10% of which is an oxygen gas and greater than or equal to 90% of which is an argon gas), and the first In—Ga—Zn—O based non-single-crystal film is formed in an oxygen atmosphere (or an atmosphere in which the oxygen gas flow rate is higher than or equal to the argon gas flow rate).

For example, the first In—Ga—Zn—O based non-single-crystal film used as the semiconductor layer 403 is formed in an argon or oxygen atmosphere using an oxide semiconductor target having a diameter of 8 inches and including In, Ga, and Zn (In₂O₃:Ga₂O₃:ZnO=1:1:1 in a molar ratio), with the distance between the substrate and the target set to 170 mm, under a pressure of 0.4 Pa, and with a direct-current (DC) power source of 0.5 kW. Note that it is preferable to use a pulsed direct-current (DC) power source, with which dust can be reduced and thickness distribution can be evened. The first In—Ga—Zn—O based non-single-crystal film has a thickness of 5 nm to 200 nm.

On the contrary, the second oxide semiconductor film used as the n⁺ layers 404a and 404b is formed by a sputtering method, which is performed using a target (In₂O₃:Ga₂O₃:ZnO=1:1:1) under deposition conditions where the pressure is 0.4 Pa, the power is 500 W, the deposition temperature is room temperature, and an argon gas is introduced at a flow rate of 40 sccm. An In—Ga—Zn—O based non-single-crystal film including crystal grains with a size of 1 nm to 10 nm immediately after the film formation is formed in some cases. Note that it can be said that the presence or absence of crystal grains or the density of crystal grains can be adjusted and the diameter size can be adjusted within the range of 1 nm to 10 nm by appropriate adjustment of the reactive sputtering deposition conditions such as the composition ratio in the target, the film deposition pressure (0.1 Pa to 2.0 Pa), the power (250 W to 3000 W:8 inches), the temperature (room temperature to 100° C.), and the like. The second In—Ga—Zn—O based non-single-crystal film has a thickness of 5 nm to 20 nm. Needless to say, when the film includes crystal grains, the size of the crystal grains does not exceed the thickness of the film. The second In—Ga—Zn—O based non-single-crystal film has a thickness of 5 nm.

Examples of a sputtering method include an RF sputtering method in which a high-frequency power source is used as a sputtering power source, a DC sputtering method, and a pulsed DC sputtering method in which a bias is applied in a pulsed manner. An RF sputtering method is mainly used in the case where an insulating film is formed, and a DC sputtering method is mainly used in the case where a metal film is formed.

In addition, there is also a multi-source sputtering apparatus in which a plurality of targets of different materials can be set. With the multi-source sputtering apparatus, films of different materials can be formed to be stacked in the same chamber, or a film of plural kinds of materials can be formed by electric discharge at the same time in the same chamber.

In addition, there are a sputtering apparatus provided with a magnet system inside the chamber and used for a magnetron sputtering, and a sputtering apparatus used for an ECR sputtering in which plasma generated with the use of microwaves is used without using glow discharge.

Furthermore, as a deposition method by sputtering, there are also a reactive sputtering method in which a target substance and a sputtering gas component are chemically reacted with each other during deposition to form a thin compound film thereof, and a bias sputtering method in which voltage is also applied to a substrate during deposition.

In the manufacturing process of the semiconductor layer, the n⁺ layers, and the wiring layers, an etching step is used to process thin films into desired shapes. Dry etching or wet etching can be used for the etching step.

As an etching gas used for dry etching, a gas containing chlorine (a chlorine-based gas such as chlorine (Cl₂), boron chloride (BCl₃), silicon chloride (SiCl₄), or carbon tetrachloride (CCl₄)) is preferable.

Alternatively, a gas containing fluorine (a fluorine-based gas such as carbon tetrafluoride (CF₄), sulfur fluoride (SF₆), nitrogen fluoride (NF₃), or trifluoromethane (CHF₃)), hydrogen bromide (HBr), oxygen (O₂), any of these gases to which a rare gas such as helium (He) or argon (Ar) is added, or the like can be used.

As an etching apparatus used for dry etching, an etching apparatus that uses reactive ion etching (RIE), or a dry etching apparatus that uses a high-density plasma source such as an electron cyclotron resonance (ECR) source or an inductively coupled plasma (ICP) source can be used. As such a dry etching apparatus with which uniform discharge can be easily obtained over a large area as compared to an ICP etching apparatus, there is an enhanced capacitively coupled plasma (ECCP) mode etching apparatus in which an upper electrode is grounded, a high-frequency power source of 13.56 MHz is connected to a lower electrode, and further a low-frequency power source of 3.2 MHz is connected to the lower electrode. This ECCP mode etching apparatus, if used, can be applied even when a substrate having the size exceeding 3 meters of the tenth generation is used as the substrate, for example.

In order to perform etching to desired shapes, etching conditions (e.g., the amount of electric power applied to a coiled electrode, the amount of electric power applied to an electrode on a substrate side, or the electrode temperature on the substrate side) are controlled as appropriate.

As an etchant used for wet etching, a mixed solution of phosphoric acid, acetic acid, and nitric acid, an ammonia peroxide mixture (hydrogen peroxide:ammonia:water=5:2:2), or the like can be used. Alternatively, ITO-07N (produced by Kanto Chemical Co., Inc.) may be used.

The etchant after the wet etching is removed by cleaning, together with the etched material. The waste liquid of the etchant including the etched material may be purified so that the included material is reused. If a material such as indium included in the oxide semiconductor layer is collected from the waste liquid of the etching and reused, resources can be used effectively and cost can be reduced.

In order to perform etching to desired shapes, etching conditions (e.g., etchant, etching time, temperature, or the like) are controlled as appropriate in accordance with the material.

As a material of the wiring layers 405a and 405b, an element selected from Al, Cr, Ta, Ti, Mo, and W, an alloy containing any of the elements as its component, an alloy containing any of the elements in combination, and the like can be given. Further, in the case of performing heat treatment at 200° C. to 600° C., the conductive film preferably has heat resistance against such heat treatment. Since use of Al alone brings disadvantages such as low resistance and a tendency to corrosion, aluminum is used in combination with a conductive material having heat resistance. As the conductive material having heat resistance which is used in combination with Al, any of the following materials may be used: an element selected from titanium (Ti), tantalum (Ta), tungsten (W), molybdenum (Mo), chromium (Cr), neodymium (Nd), and scandium (Sc), an alloy containing any of the above elements as a component, an alloy containing any of the above elements in combination, and a nitride containing any of the above elements as a component.

The gate insulating layer 402, the semiconductor layer 403, the n⁺ layers 404a and 404b, and the wiring layers 405a and 405b may be formed in succession without being exposed to air. By successive formation without exposure to air, each interface between the stacked layers can be formed without being contaminated by atmospheric components or contaminating impurities contained in air; therefore, variation in characteristics of the thin film transistor can be reduced.

Note that the semiconductor layer 403 is partially etched and has a groove (a depression portion).

The semiconductor layer 403 and the n⁺ layers 404a and 404b are preferably subjected to heat treatment at 200° C. to 600° C., typically 300° C. to 500° C. For example, heat treatment is performed for 1 hour at 350° C. in a nitrogen atmosphere. By this heat treatment, rearrangement at the atomic level is caused in the In—Ga—Zn—O based oxide semiconductor which forms the semiconductor layer 403 and the n⁺ layers 404a and 404b. This heat treatment (also including photo-annealing or the like) is important in that the distortion that interrupts carrier transfer in the semiconductor layer 403 and the n⁺ layers 404a and 404b can be reduced. Note that there is no particular limitation on when to perform the heat treatment, as long as it is performed after the semiconductor layer 403 and the n⁺ layers 404a and 404b are formed.

In addition, oxygen radical treatment may be performed on the exposed depression portion of the semiconductor layer 403. The radical treatment is preferably performed in an atmosphere of O₂ or N₂O, or an atmosphere of N₂, He, Ar, or the like which includes oxygen. Alternatively, an atmosphere obtained by adding Cl₂ or CF₄ to the above atmosphere may be used. Note that the radical treatment is preferably performed with no bias voltage applied to the first light-transmitting substrate 441 side.

The insulating film 407 covering the thin film transistor 420 can be formed using an inorganic insulating film or organic insulating film formed by a wet method or a dry method. For example, the insulating film 407 can be formed by a CVD method, a sputtering method, or the like using a silicon nitride film, a silicon oxide film, a silicon oxynitride film, an aluminum oxide film, a tantalum oxide film, or the like. Alternatively, an organic material such as polyimide, acrylic, benzocyclobutene, polyamide, or an epoxy resin can be used. Other than such organic materials, it is also possible to use a low-dielectric constant material (a low-k material), a siloxane-based resin, PSG (phosphosilicate glass), BPSG (borophosphosilicate glass), or the like.

Alternatively, the insulating film 407 may be formed by stacking plural insulating films formed using any of these materials. For example, the insulating film 407 may have such a structure that an organic resin film is stacked over an inorganic insulating film.

Further, by using a resist mask which is formed using a multi-tone mask and has regions with plural thicknesses (typically, two different thicknesses), the number of resist masks can be reduced, resulting in simplified process and lower cost.

Improvement in contrast and viewing angle characteristics enables a liquid crystal display device with higher image quality to be supplied. Further, such a liquid crystal display device can be manufactured at low cost with high productivity.

Characteristics of the thin film transistor are stabilized and the liquid crystal display device can have higher reliability.

Although a channel-etch type, which is a structure of an inverted staggered type, is described as an example in this embodiment, the structure of the thin film transistor is not particularly limited and may be a channel-stop type. Alternatively, the structure of the thin film transistor may be a bottom-contact structure (also called an inverted coplanar type).

### Embodiment 3

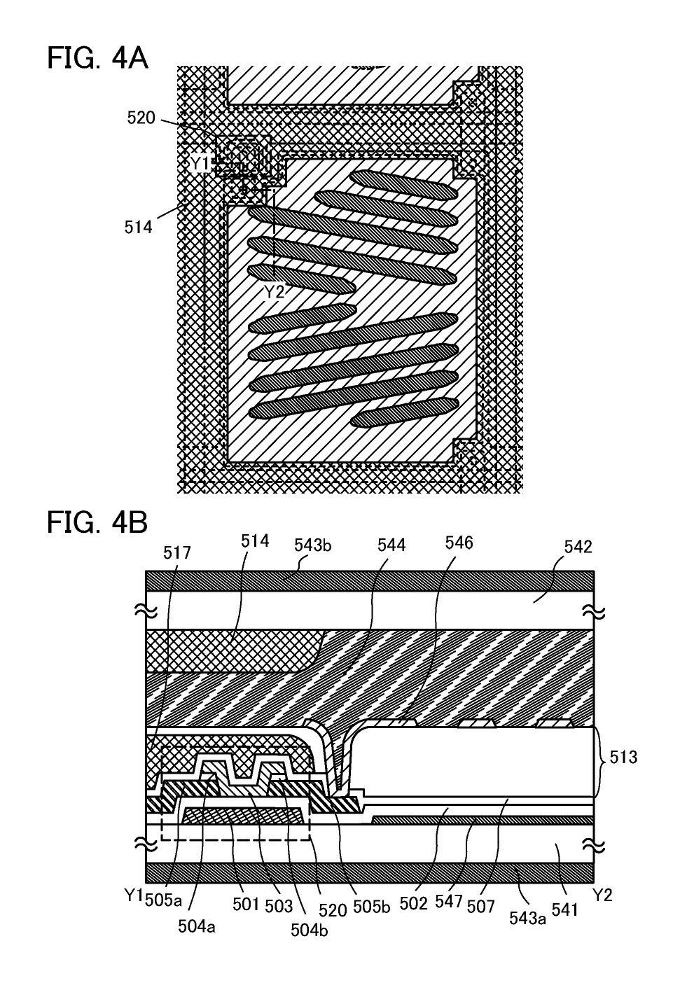

Another mode of a liquid crystal display device is illustrated in FIGS. 4A and 4B. Specifically, an example of a liquid crystal display device in which a first electrode layer with a flat shape formed below an interlayer insulating film is used as a common electrode layer and a second electrode layer having an opening pattern formed over the interlayer insulating film is used as a pixel electrode layer will be described.

FIG. 4A is a plan view of a liquid crystal display device illustrating one pixel. FIG. 4B is a cross-sectional view taken along line Y1-Y2 in FIG. 4A.

As an example, in the liquid crystal display device illustrated in FIGS. 4A and 4B, a light-blocking layer 517 is formed on the side of the first light-transmitting substrate 541, which is an element substrate, as part of an interlayer insulating film 513. A second electrode layer 546 which is electrically connected to a thin film transistor 520 serves as a pixel electrode layer, and a first electrode layer 547 which is electrically connected to a common wiring layer serves as a common electrode layer. The electrode structure illustrated in FIGS. 4A and 4B is an electrode structure used in an FFS mode.

In a lateral electric field mode such as an FFS mode, a second electrode layer (e.g., a pixel electrode layer with which voltage is controlled per pixel) having an opening pattern is located below a liquid crystal layer, and a first electrode layer (e.g., a common electrode layer with which common voltage is applied to all pixels) with a flat shape is located below the opening pattern. Therefore, the first electrode layer and the second electrode layer, one of which is a pixel electrode layer and the other of which is a common electrode layer, are formed over the first light-transmitting substrate 541, and the pixel electrode layer and the common electrode layer are arranged to be stacked with an insulating film (or an interlayer insulating layer) interposed therebetween. One of the pixel electrode layer and the common electrode layer is formed below the other and has a flat shape, and the other is formed over the one and has various opening patterns including a bent portion or a branching comb-shaped portion. The first electrode layer 547 and the second electrode layer 546 are arranged so as not to have the same shape and overlap with each other, in order to generate an electric field therebetween.

Note that a capacitor is formed by the pixel electrode layer and the common electrode layer. Although the common electrode layer can operate in a floating state (an electrically isolated state), the potential of the common electrode layer may be set to a fixed potential, preferably to a potential around a common potential (an intermediate potential of an image signal which is transmitted as data) in such a level as not to generate flickers.

The interlayer insulating film 513 includes the light-blocking layer 517 and a light-transmitting resin layer. The light-blocking layer 517 is provided on the first light-transmitting substrate 541 (element substrate) side and formed over the thin film transistor 520 (at least in a region which covers a semiconductor layer of the thin film transistor) with an insulating film 507 interposed therebetween, so that the light-blocking layer 517 serves as a light-blocking layer for the semiconductor layer. On the contrary, the light-transmitting resin layer is formed so as to overlap with the first electrode layer 547 and the second electrode layer 546 and serves as a display region.

The visible light transmittance of the light-blocking layer 517 is lower than that of a semiconductor layer 503 which is an oxide semiconductor layer.

Since the light-blocking layer 517 is used in the interlayer film, it is preferable that black organic resin be used for the light-blocking layer 517. For example, a black resin of a pigment material, carbon black, titanium black, or the like may be mixed into a resin material such as photosensitive or non-photosensitive polyimide. As the formation method of the light-blocking layer 517, a wet method such as spin coating, dip coating, spray coating, droplet discharging (e.g., ink jetting, screen printing, or offset printing), or the like may be used in accordance with the material. If needed, an etching method (dry etching or wet etching) may be employed to form a desired pattern. The thickness of the light-blocking layer 517 is 0.5 μm to 2 μm. If importance is put on planarity of the interlayer insulating film 513, the thickness of the light-blocking layer 517 is preferably 1 μm or less since the region where the light-blocking layer 517 is provided overlaps with the thin film transistor and is likely to be thick.

In this embodiment, a light-blocking layer 514 is further formed on the second light-transmitting substrate 542 (counter substrate) side of the liquid crystal display device. Since a light-emitting diode has a higher luminance than a cold-cathode tube, in the case of using the light-emitting diode in a backlight portion, the light-blocking layer is preferably formed thick. Although the thickness of a light-blocking layer obtained by one-time film formation is limited, when a light-blocking layer is formed on each substrate, the thickness of the light-blocking layer can become a sum of the thicknesses of the light-blocking layer 514 and the light-blocking layer 517, which is preferable. For example, the thickness of the light-blocking layer 514 is set at 1.8 μm and the thickness of the light-blocking layer 517 is set at 1 μm; in this case, the thickness is 2.8 μm in total. By making the total thickness of the light-blocking layer large, contrast can be increased and the thin film transistor can be stabilized more. In the case of forming the light-blocking layer 514 on the counter substrate side, if the light-blocking layer is formed in a region corresponding to the thin film transistor with the liquid crystal layer interposed therebetween (at least in a region which overlaps with the semiconductor layer of the thin film transistor), electric characteristics of the thin film transistor can be prevented from being varied due to incident light from the counter substrate side.

In the case of forming the light-blocking layer 514 on the counter substrate side, there is a case in which transmitted light from the element substrate side and transmitted light from the counter substrate side to the semiconductor layer of the thin film transistor can be blocked by a light-blocking wiring layer, an electrode layer, or the like. Thus, the light-blocking layer 514 need not always be formed to cover the thin film transistor.

When the light-blocking layers are provided in this manner, incident light on the semiconductor layer of the thin film transistor can be blocked by the light-blocking layers without reduction in an aperture ratio of a pixel. Accordingly, electric characteristics of the thin film transistor can be prevented from being varied due to photosensitivity of the oxide semiconductor and can be stabilized. Further, the light-blocking layer can prevent light leakage to an adjacent pixel, which enables higher contrast and higher definition display. Therefore, high definition and high reliability of the liquid crystal display device can be achieved.

The thin film transistor 520 is a bottom-contact (also called an inverted coplanar) thin film transistor and includes, over the first light-transmitting substrate 541 that is a substrate having an insulating surface, a gate electrode layer 501, a gate insulating layer 502, wiring layers 505a and 505b serving as a source electrode layer and a drain electrode layer, n⁺ layers 504a and 504b serving as a source region and a drain region, and the semiconductor layer 503. In addition, the insulating film 507 which covers the thin film transistor 520 and is in contact with the semiconductor layer 503 is provided. The first electrode layer 547 is formed in the same layer as the gate electrode layer 501 over the first light-transmitting substrate 541 and is a flat electrode layer in the pixel.

It is preferable that reverse sputtering in which an argon gas is introduced to generate plasma be performed on the gate insulating layer 502 and the wiring layers 505a and 505b before the formation of the semiconductor layer 503 by a sputtering method, in order to remove dust attached to surfaces.

The semiconductor layer 503 and the n⁺ layers 504a and 504b are preferably subjected to heat treatment at 200° C. to 600° C., typically 300° C. to 500° C. For example, heat treatment is performed for 1 hour at 350° C. in an air atmosphere or a nitrogen atmosphere. There is no particular limitation on when to perform this heat treatment, as long as it is performed after the oxide semiconductor films used for the semiconductor layer 503 and the n⁺ layers 504a and 504b are formed.

An In—Ga—Zn—O based non-single-crystal film is used for the semiconductor layer 503 and the n⁺ layers 504a and 504b. The thin film transistor 520 having such a structure shows characteristics of a mobility of 20 cm²/Vs or more and a subthreshold swing (S value) of 0.4 V/dec or less. Thus, the thin film transistor can operate at high speed, and a driver circuit (a source driver or a gate driver) such as a shift register can be formed over the same substrate as the pixel portion.

This embodiment can be implemented in combination with any of the structures disclosed in other embodiments as appropriate.

### Embodiment 4

A thin film transistor is manufactured, and a liquid crystal display device having a display function can be manufactured using the thin film transistor in a pixel portion and further in a driver circuit. Further, part or whole of a driver circuit can be formed over the same substrate as a pixel portion, using a thin film transistor, whereby a system-on-panel can be obtained.

The liquid crystal display device includes a liquid crystal element (also referred to as a liquid crystal display element) as a display element.

Further, a liquid crystal display device includes a panel in which a display element is sealed, and a module in which an IC or the like including a controller is mounted to the panel. The present invention further relates to one mode of an element substrate before the display element is completed in a manufacturing process of the liquid crystal display device, and the element substrate is provided with a means to supply current to the display element in each of a plurality of pixels. Specifically, the element substrate may be in a state after only a pixel electrode of the display element is formed, a state after a conductive film to be a pixel electrode is formed and before the conductive film is etched to form the pixel electrode, or any of other states.

Note that a liquid crystal display device in this specification means an image display device, a display device, or a light source (including a lighting device). Further, the liquid crystal display device includes any of the following modules in its category: a module to which a connector such as an FPC (flexible printed circuit), TAB (tape automated bonding) tape, or a TCP (tape carrier package) is attached; a module having a TAB tape or a TCP at the tip of which a printed wiring board is provided; and a module in which an integrated circuit (IC) is directly mounted on a display element by chip on glass (COG).

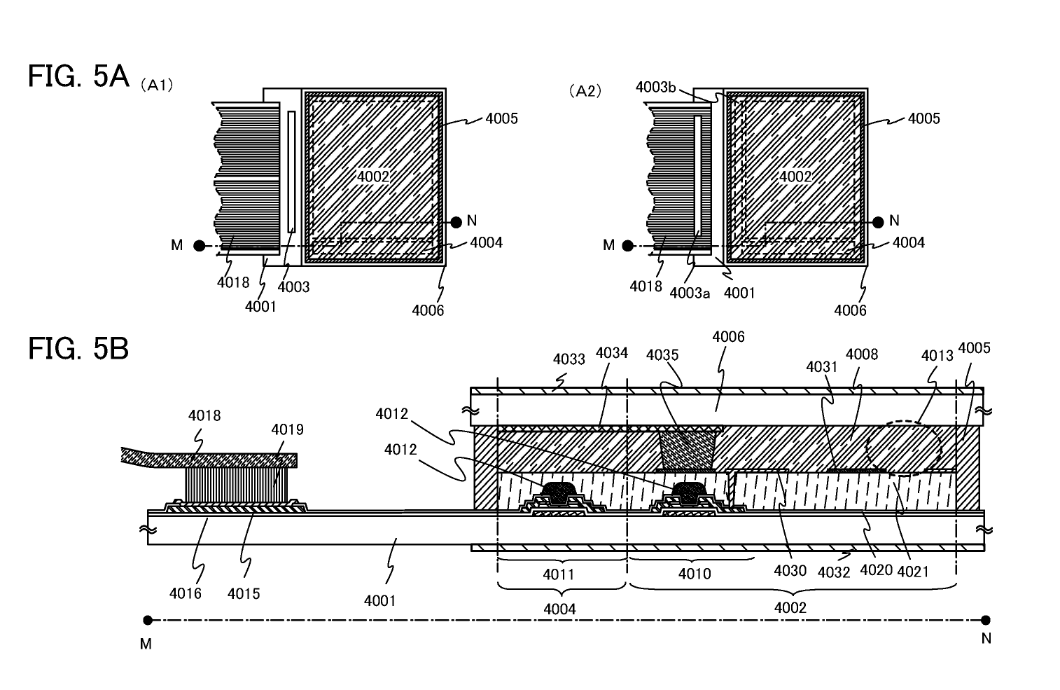

The appearance and a cross section of a liquid crystal display panel, which is one embodiment of a liquid crystal display device, will be described with reference to FIGS. 5A1, 5A2, and 5B. FIGS. 5A1 and 5A2 are top views of a panel in which highly reliable thin film transistors 4010 and 4011 each including an oxide semiconductor film as a semiconductor layer and a liquid crystal element 4013 are sealed between a first substrate 4001 and a second substrate 4006 with a sealant 4005. FIG. 5B is a cross-sectional view taken along line M-N of FIGS. 5A1 and 5A2.

The sealant 4005 is provided so as to surround a pixel portion 4002 and a scanning line driver circuit 4004 which are provided over the first substrate 4001. The second substrate 4006 is provided over the pixel portion 4002 and the scanning line driver circuit 4004. Therefore, the pixel portion 4002 and the scanning line driver circuit 4004 are sealed together with a liquid crystal layer 4008, by the first substrate 4001, the sealant 4005, and the second substrate 4006.

In FIG. 5A1, a signal line driver circuit 4003 that is formed using a single crystal semiconductor film or a polycrystalline semiconductor film over a substrate separately prepared is mounted in a region that is different from the region surrounded by the sealant 4005 over the first substrate 4001. On the contrary, FIG. 5A2 illustrates an example in which part of a signal line driver circuit is formed over the first substrate 4001 with the use of a thin film transistor that uses an oxide semiconductor. A signal line driver circuit 4003b is formed over the first substrate 4001 and a signal line driver circuit 4003a that is formed using a single crystal semiconductor film or a polycrystalline semiconductor film is mounted on the substrate separately prepared.

Note that there is no particular limitation on the connection method of a driver circuit which is separately formed, and a COG method, a wire bonding method, a TAB method, or the like can be used. FIG. 5A1 illustrates an example of mounting the signal line driver circuit 4003 by a COG method, and FIG. 5A2 illustrates an example of mounting the signal line driver circuit 4003 by a TAB method.

The pixel portion 4002 and the scanning line driver circuit 4004 provided over the first substrate 4001 include a plurality of thin film transistors. FIG. 5B illustrates the thin film transistor 4010 included in the pixel portion 4002 and the thin film transistor 4011 included in the scanning line driver circuit 4004. An insulating layer 4020 and an interlayer film 4021 are provided over the thin film transistors 4010 and 4011.

Any of the highly reliable thin film transistors including an oxide semiconductor film as a semiconductor layer, which are described in Embodiments 1 to 8, can be used as the thin film transistors 4010 and 4011. The thin film transistors 4010 and 4011 are n-channel thin film transistors.

A pixel electrode layer 4030 and a common electrode layer 4031 are provided over the first substrate 4001, and the pixel electrode layer 4030 is electrically connected to the thin film transistor 4010. The liquid crystal element 4013 includes the pixel electrode layer 4030, the common electrode layer 4031, and the liquid crystal layer 4008. Note that a polarizing plate 4032 and a polarizing plate 4033 are provided on the outer sides of the first substrate 4001 and the second substrate 4006, respectively. The pixel electrode layer 4030 and the common electrode layer 4031 may have the structure described in Embodiment 2; in such a case, the common electrode layer 4031 may be provided on the second substrate 4006 side, and the pixel electrode layer 4030 and the common electrode layer 4031 may be stacked with the liquid crystal layer 4008 interposed therebetween.

As the first substrate 4001 and the second substrate 4006, glass, plastic, or the like having a light-transmitting property can be used. As plastic, a fiberglass-reinforced plastics (FRP) plate, a polyvinyl fluoride (PVF) film, a polyester film, or an acrylic resin film can be used. Further, sheet in which aluminum foil is sandwiched by PVF films or polyester films can also be used.

A columnar spacer denoted by reference numeral 4035 is obtained by selective etching of an insulating film and is provided in order to control the thickness (a cell gap) of the liquid crystal layer 4008. Note that a spherical spacer may be used.

FIGS. 5A1, 5A2, and 5B illustrate examples of liquid crystal display devices in which a polarizing plate is provided on the outer side (the view side) of a pair of substrates; however, the polarizing plates may be provided on the inner side of the pair of the substrates. Whether the polarizing plate is provided on the inner side or the outer side may be determined as appropriate depending on the material of the polarizing plate and conditions of the manufacturing process. Furthermore, a light-blocking layer serving as a black matrix may be provided.

The interlayer film 4021 is a light-transmitting resin layer, and light-blocking layers 4012 are formed in part of the interlayer film 4021. The light-blocking layers 4012 cover the thin film transistors 4010 and 4011. In FIGS. 5A1, 5A2, and 5B, a light-blocking layer 4034 is provided on the second substrate 4006 side so as to cover the thin film transistors 4010 and 4011. By the light-blocking layers 4012 and the light-blocking layer 4034, contrast can be increased and the thin film transistors can be stabilized more.

When the light-blocking layer 4034 is provided, the intensity of incident light on the semiconductor layers of the thin film transistors can be attenuated; accordingly, electric characteristics of the thin film transistors can be prevented from being varied due to photosensitivity of the oxide semiconductor and can be stabilized.

The thin film transistors may be covered with the insulating layer 4020 which serves as a protective film of the thin film transistors; however, there is no particular limitation to such a structure.

Note that the protective film is provided to prevent entry of impurities floating in air, such as an organic substance, a metal substance, or moisture, and is preferably a dense film. The protective film may be formed by a sputtering method to have a single-layer structure or a stacked structure including a silicon oxide film, a silicon nitride film, a silicon oxynitride film, a silicon nitride oxide film, an aluminum oxide film, an aluminum nitride film, an aluminum oxynitride film, and/or an aluminum nitride oxide film.

After the protective film is formed, the semiconductor layers may be subjected to annealing (300° C. to 400° C.).

Further, in the case of further forming a light-transmitting insulating layer as a planarizing insulating film, the light-transmitting insulating layer can be formed using an organic material having heat resistance, such as polyimide, acrylic, benzocyclobutene, polyamide, or epoxy. Other than such organic materials, it is also possible to use a low-dielectric constant material (a low-k material), a siloxane-based resin, PSG (phosphosilicate glass), BPSG (borophosphosilicate glass), or the like. The insulating layer may be formed by stacking a plurality of insulating films formed of these materials.

A method for forming the insulating layer is not particularly limited, and the following method can be employed in accordance with the material: sputtering, an SOG method, spin coating, dip coating, spray coating, droplet discharging (e.g., ink jetting, screen printing, or offset printing), doctor knife, roll coating, curtain coating, knife coating, or the like. In the case where the insulating layer is formed using a material solution, the semiconductor layers may be annealed (at 200° C. to 400° C.) at the same time of a baking step. The baking step of the insulating layer serves also as the annealing step of the semiconductor layers, and thereby a liquid crystal display device can be manufactured efficiently.

The pixel electrode layer 4030 and the common electrode layer 4031 can be formed using a light-transmitting conductive material such as indium oxide containing tungsten oxide, indium zinc oxide containing tungsten oxide, indium oxide containing titanium oxide, indium tin oxide containing titanium oxide, indium tin oxide (hereinafter referred to as ITO), indium zinc oxide, or indium tin oxide to which silicon oxide is added.

A conductive composition containing a conductive high molecule (also referred to as a conductive polymer) can be used for the pixel electrode layer 4030 and the common electrode layer 4031.

In addition, a variety of signals and potentials are supplied to the signal line driver circuit 4003 that is formed separately, and the scanning line driver circuit 4004 or the pixel portion 4002 from an FPC 4018.

Further, since the thin film transistor is easily broken by static electricity and the like, a protection circuit for protecting the driver circuit is preferably provided over the same substrate for a gate line or a source line. The protection circuit is preferably formed using a nonlinear element in which an oxide semiconductor is used.

In FIGS. 5A1, 5A2, and 5B, a connection terminal electrode 4015 is formed using the same conductive film as that of the pixel electrode layer 4030, and a terminal electrode 4016 is formed using the same conductive film as that of source and drain electrode layers of the thin film transistors 4010 and 4011.

The connection terminal electrode 4015 is electrically connected to a terminal included in the FPC 4018 through an anisotropic conductive film 4019.

Although FIGS. 5A1, 5A2, and 5B illustrate an example in which the signal line driver circuit 4003 is formed separately and mounted on the first substrate 4001, the present invention is not limited to this structure. The scanning line driver circuit may be formed separately and then mounted, or only a part of the signal line driver circuit or a part of the scanning line driver circuit may be formed separately and then mounted.

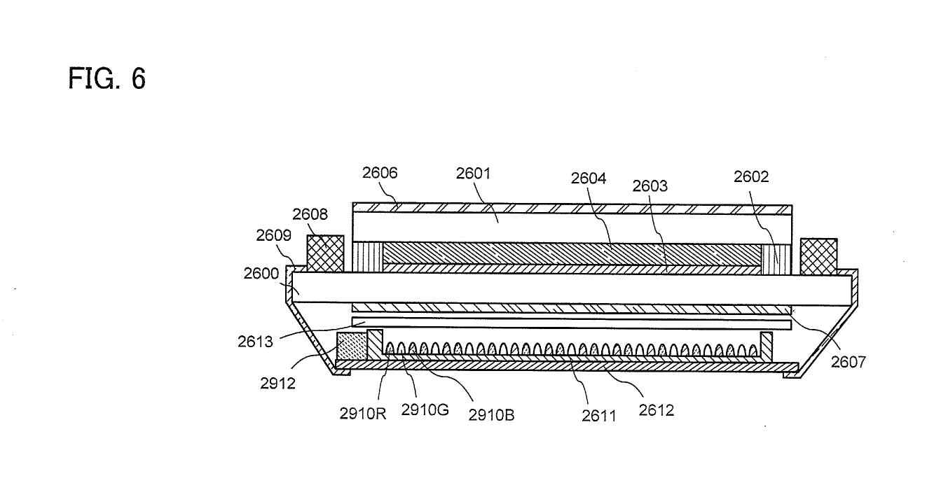

FIG. 6 illustrates an example of a cross-sectional structure of a liquid crystal display device, in which an element substrate 2600 and a counter substrate 2601 are attached to each other with a sealant 2602, and an element layer 2603 including a TFT or the like and a liquid crystal layer 2604 are provided between the substrates.

In the case where color display is performed, light-emitting diodes which emit lights of plural colors are arranged in a backlight portion. In the case of an RGB mode, a red light-emitting diode 2910R, a green light-emitting diode 2910G, and a blue light-emitting diode 2910B are disposed in each of the regions into which a display area of the liquid crystal display device is divided.

A polarizing plate 2606 is provided on the outer side of the counter substrate 2601, and a polarizing plate 2607 and an optical sheet 2613 are provided on the outer side of the element substrate 2600. A light source is formed using the red light-emitting diode 2910R, the green light-emitting diode 2910G, the blue light-emitting diode 2910B, and a reflective plate 2611. An LED control circuit 2912 provided for a circuit substrate 2612 is connected to a wiring circuit portion 2608 of the element substrate 2600 through a flexible wiring board 2609 and further includes an external circuit such as a control circuit or a power source circuit.

The LEDs are individually made to emit light by this LED control circuit 2912; thus, a field-sequential liquid crystal display device is formed.

This embodiment can be implemented in combination with any of the structures disclosed in other embodiments as appropriate.

### Embodiment 5

A liquid crystal display device disclosed in this specification can be applied to a variety of electronic devices (including a game machine). Examples of electronic devices include television sets (also referred to as televisions or television receivers), monitors of computers or the like, cameras such as digital cameras or digital video cameras, digital photo frames, mobile phones (also referred to as cellular phones or mobile phone sets), portable game consoles, portable information terminals, audio reproducing devices, large-sized game machines such as pachinko machines, and the like.

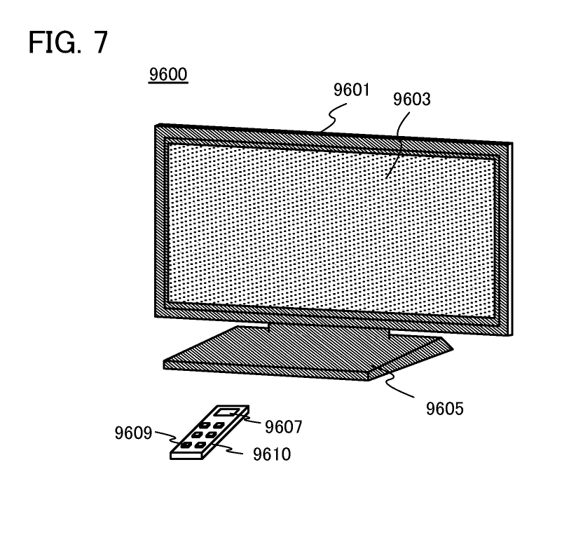

FIG. 7 illustrates an example of a television set 9600. In the television set 9600, a display portion 9603 is incorporated in a housing 9601. Images can be displayed on the display portion 9603. Here, the housing 9601 is supported by a stand 9605.

The television set 9600 can be operated with an operation switch of the housing 9601 or a separate remote controller 9610. Channels and volume can be controlled with an operation key 9609 of the remote controller 9610 so that an image displayed on the display portion 9603 can be controlled. Furthermore, the remote controller 9610 may be provided with a display portion 9607 for displaying data output from the remote controller 9610.

Note that the television set 9600 is provided with a receiver, a modem, and the like. With the receiver, a general television broadcast can be received. Furthermore, when the television set 9600 is connected to a communication network by wired or wireless connection via the modem, one-way (from a transmitter to a receiver) or two-way (between a transmitter and a receiver, between receivers, or the like) data communication can be performed.

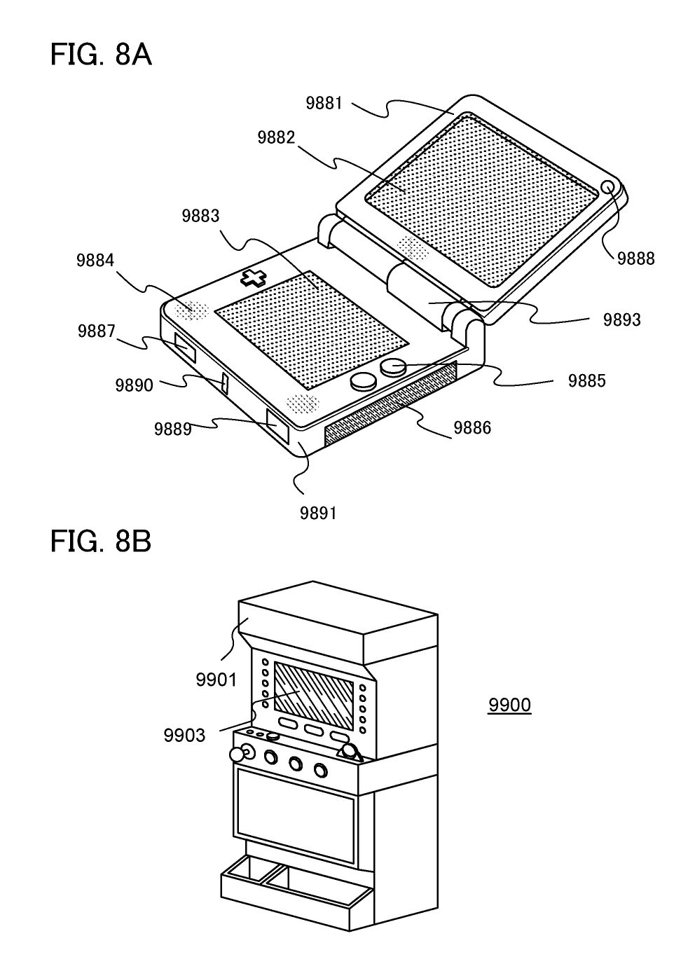

FIG. 8A illustrates a portable game machine including a housing 9881 and a housing 9891 which are jointed with a connector 9893 so as to be able to open and close. A display portion 9882 and a display portion 9883 are incorporated in the housing 9881 and the housing 9891, respectively. The portable game machine illustrated in FIG. 8A additionally includes a speaker portion 9884, a storage medium insertion portion 9886, an LED lamp 9890, an input means (operation keys 9885, a connection terminal 9887, a sensor 9888 (a sensor having a function of measuring force, displacement, position, speed, acceleration, angular speed, the number of rotations, distance, light, liquid, magnetism, temperature, chemical substance, sound, time, hardness, electric field, current, voltage, electric power, radiation, flow rate, humidity, tilt angle, vibration, smell, or infrared ray), a microphone 9889), and the like. It is needless to say that the structure of the portable game machine is not limited to the above and other structures provided with at least a liquid crystal display device disclosed in this specification may be employed. The portable game machine may include other accessory equipments as appropriate. The portable game machine illustrated in FIG. 8A has a function of reading out a program or data stored in a storage medium to display it on the display portion, and a function of sharing information with another portable game machine by wireless communication. The portable game machine in FIG. 8A can have various functions without limitation to the above.

FIG. 8B illustrates an example of a slot machine 9900 which is a large-sized game machine. In the slot machine 9900, a display portion 9903 is incorporated in a housing 9901. In addition, the slot machine 9900 includes an operation means such as a start lever or a stop switch, a coin slot, a speaker, and the like. It is needless to say that the structure of the slot machine 9900 is not limited to the above and other structures provided with at least a liquid crystal display device disclosed in this specification may be employed. The slot machine may include other accessory equipments as appropriate.

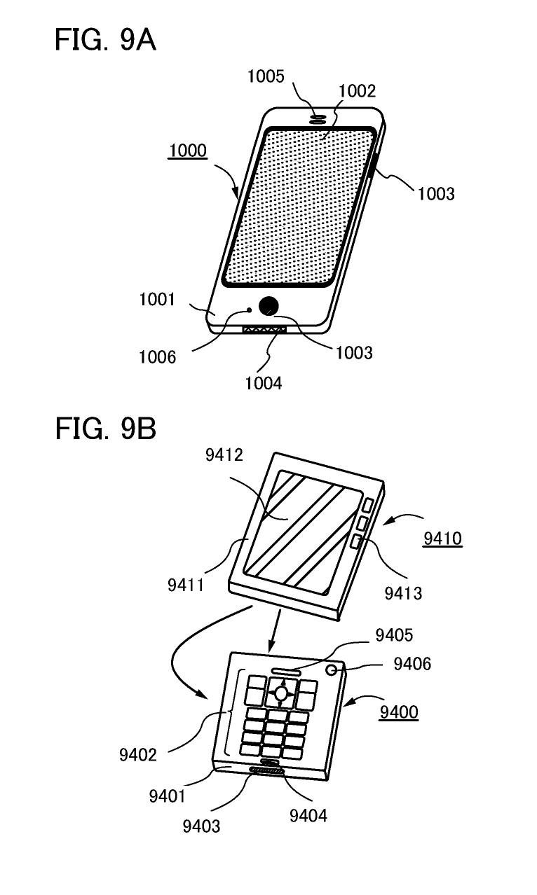

FIG. 9A illustrates an example of a mobile phone 1000. The mobile phone 1000 is provided with a display portion 1002 incorporated in a housing 1001, operation buttons 1003, an external connection port 1004, a speaker 1005, a microphone 1006, and the like.

When the display portion 1002 of the mobile phone 1000 illustrated in FIG. 9A is touched with a finger or the like, data can be input into the mobile phone 1000. Furthermore, operations such as making calls and composing mails can be performed by touching the display portion 1002 with a finger or the like.

There are mainly three screen modes of the display portion 1002. The first mode is a display mode mainly for displaying an image. The second mode is an input mode mainly for inputting information such as text. The third mode is a display-and-input mode in which two modes of the display mode and the input mode are mixed.

For example, in the case of making a call or composing a mail, a text input mode mainly for inputting text is selected for the display portion 1002 so that text displayed on a screen can be input. In that case, it is preferable to display a keyboard or number buttons on almost all the area of the screen of the display portion 1002.

When a detection device including a sensor for detecting inclination, such as a gyroscope or an acceleration sensor, is provided inside the mobile phone 1000, display on the screen of the display portion 1002 can be automatically switched by determining the direction of the mobile phone 1000 (whether the mobile phone 1000 is placed horizontally or vertically for a landscape mode or a portrait mode).

The screen mode is switched by touching the display portion 1002 or operating the operation buttons 1003 of the housing 1001. Alternatively, the screen mode can be switched depending on the kind of images displayed on the display portion 1002. For example, when a signal of an image displayed on the display portion is of moving image data, the screen mode is switched to the display mode. When the signal is of text data, the screen mode is switched to the input mode.

Furthermore, in the input mode, when input by touching the display portion 1002 is not performed for a certain period while a signal is detected by the optical sensor in the display portion 1002, the screen mode may be controlled so as to be switched from the input mode to the display mode.

The display portion 1002 can also function as an image sensor. For example, an image of a palm print, a fingerprint, or the like is taken by touching the display portion 1002 with the palm or the finger, whereby personal authentication can be performed. Furthermore, by providing a backlight or a sensing light source emitting a near-infrared light for the display portion, an image of a finger vein, a palm vein, or the like can also be taken.

FIG. 9B also illustrates an example of a mobile phone. The mobile phone illustrated in FIG. 9B includes a display device 9410 having a display portion 9412 and operation buttons 9413 in a housing 9411 and a communication device 9400 having scan buttons 9402, an external input terminal 9403, a microphone 9404, a speaker 9405, and a light-emitting portion 9406 which emits light when receiving a call in a housing 9401. The display device 9410 having a display function can be detached from or attached to the communication device 9400 having a telephone function in two directions indicated by the arrows. Accordingly, the display device 9410 and the communication device 9400 can be attached to each other along their short sides or long sides. In addition, when only the display function is needed, the display device 9410 can be detached from the communication device 9400 and used alone. Images or input information can be transmitted or received by wireless or wired communication between the communication device 9400 and the display device 9410, each of which has a rechargeable battery.

The present invention including the above-described structure will be described in more detail in the following example.

### Example 1

In Example 1, an example of manufacturing a field-sequential liquid crystal display device by a liquid crystal injection method will be described.

A TFT was formed over a first light-transmitting substrate, and then a black matrix (a BM) and a protective film were formed. After opening a contact hole, a pixel electrode was formed. Further, a common electrode was formed over the first light-transmitting substrate in a similar manner so that the pixel electrode and the common electrode form a comb shape. Then, a columnar spacer was provided in a region of the pixel portion, in which an opening was not formed.

Then, a transparent conductive film was formed over a second light-transmitting substrate and a columnar spacer was formed in a similar manner to that of the first light-transmitting substrate. The position of the spacers was determined so that the columnar spacer formed over the first light-transmitting substrate and the columnar spacer formed over the second light-transmitting substrate overlap with each other when the first light-transmitting substrate and the second light-transmitting substrate are attached to each other.

Here, formation of an alignment film for controlling the alignment of a liquid crystal and alignment treatment such as rubbing were not performed on the first light-transmitting substrate and the second light-transmitting substrate. In this example, RGB diodes (LEDs) were arranged as a backlight and a field-sequential system was employed; therefore, a color filter was not provided over the first light-transmitting substrate and the second light-transmitting substrate.

Next, a heat-curable sealant was applied over the second light-transmitting substrate, and the first light-transmitting substrate and the second light-transmitting substrate were attached to each other. The accuracy of the attachment was in the range of from +1 μm to −1 μm. The distance between the first light-transmitting substrate and the second light-transmitting substrate was kept with a distance-keeping agent such as a columnar spacer or a spherical spacer. Then, while a pressure (2.94 N/cm²) was applied, the sealant was baked for 3 hours in an oven at 160° C.

Next, the attached first and second light-transmitting substrates were divided with a scriber and an FPC was attached.

A liquid crystal mixture used in this example is a mixture which includes a liquid crystal whose dielectric constant anisotropy is positive, a chiral agent, a UV curable resin, and a polymerization initiator. There is a possibility that the UV curable resin and the polymerization initiator might undergo self-polymerization before UV irradiation. Therefore, the liquid crystal and the chiral agent were mixed first so that the phase was made to be a cholesteric phase, and then heated to an isotropic phase so that the pitch became 400 nm or less. After sufficient stirring, the UV curable resin and the polymerization initiator were mixed at a room temperature. Then, stirring was performed at a temperature that is about 2° C. higher than the melting point of the UV curable resin and the polymerization initiator.

Next, this liquid crystal mixture was vacuum-injected while being heated. After the injection, the injection hole was sealed, and polymer stabilization treatment was performed. The polymer stabilization treatment was performed in the following manner: the pair of substrates between which the liquid crystal layer was sandwiched was put in an oven and heated to an isotropic phase. Then, the temperature was decreased at −0.5° C./min, so that the phase was changed to a blue phase. Next, under the state in which the temperature decrease was stopped at the blue phase and the temperature was kept at a certain degree, polymer stabilization was performed by irradiation from both above and below the pair of substrates with a UV light source (a main wavelength of 365 nm, 2 mW/cm²) for 20 minutes. The oven was used for this step since the step cannot be performed with a hot plate that is a metal plate which does not transmit visible light and ultraviolet light. Further, since the second light-transmitting substrate is not provided with a BM, the whole liquid crystal layer can be irradiated with ultraviolet light. On the other hand, since the first light-transmitting substrate is provided with the BM having a light-blocking property and the like, only a region of the liquid crystal layer, which overlaps with the pixel opening portion is irradiated with ultraviolet light. However, since a field-sequential system in which a color filter need not be provided was employed, the pixel opening portion was irradiated with almost the same amount of ultraviolet light from both the first light-transmitting substrate and the second light-transmitting substrate. Accordingly, a polymer was evenly distributed without being unevenly distributed to one substrate side, that is, either the first light-transmitting substrate side or the second light-transmitting substrate side. In addition, two polarizing plates were attached to outer sides of the first light-transmitting substrate and the second light-transmitting substrate so that the two polarizing plates were arranged to form 45° with the comb-shaped electrodes. Thus, a liquid crystal panel was manufactured.

An example of sealing the injection hole after injection and then performing polymer stabilization treatment is described in this example. However, in the case of using a UV curable resin for sealing, it is preferable that polymer stabilization treatment be performed after injection and then sealing be performed, since there is a possibility that the UV curable resin included in the liquid crystal mixture might be cured by UV irradiation for sealing.

In the above-described manner, by performing the UV irradiation step of the polymer stabilization treatment from both the first light-transmitting substrate and the second light-transmitting substrate at the same time, residual birefringence is not caused after voltage application is stopped; accordingly, the same black display as before the voltage application can be obtained and leakage of light can be reduced. Accordingly, a polymer-stabilized blue-phase display element with high quality can be manufactured.

This application is based on Japanese Patent Application serial no. 2008-330915 filed with Japan Patent Office on Dec. 25, 2008, the entire contents of which are hereby incorporated by reference.

1. A manufacturing method of a semiconductor device, comprising the steps of:
forming, over a first light-transmitting substrate, a gate electrode, a light-blocking layer, and a thin film transistor including an oxide semiconductor layer between the gate electrode and the light-blocking layer;
forming a pixel portion including a pixel electrode which is electrically connected to the thin film transistor;
fixing the first light-transmitting substrate and a second light-transmitting substrate to each other with a liquid crystal layer including a photocurable resin and a photopolymerization initiator interposed therebetween;
irradiating the liquid crystal layer with ultraviolet light from both above and below the first light-transmitting substrate and the second light-transmitting substrate;
fixing a first polarizing plate to the first light-transmitting substrate and a second polarizing plate to the second light-transmitting substrate after irradiation of the liquid crystal layer with the ultraviolet light; and
fixing a backlight portion including plural kinds of light-emitting diodes so as to overlap with the pixel portion of the first light-transmitting substrate.

2. The manufacturing method of a semiconductor device according to claim 1, wherein the liquid crystal layer includes a liquid crystal material exhibiting a blue phase.

3. The manufacturing method of a semiconductor device according to claim 1, wherein the liquid crystal layer includes a chiral agent.

4. A manufacturing method of a semiconductor device, comprising the steps of:
forming, over a first light-transmitting substrate, a gate electrode and a thin film transistor including an oxide semiconductor layer which overlaps with the gate electrode;
forming a pixel portion including a pixel electrode which is electrically connected to the thin film transistor;
fixing a second light-transmitting substrate provided with a light-blocking layer to the first light-transmitting substrate with a liquid crystal layer including a photocurable resin and a photopolymerization initiator interposed therebetween;
irradiating the liquid crystal layer with ultraviolet light from both above and below the first light-transmitting substrate and the second light-transmitting substrate;
fixing a first polarizing plate to the first light-transmitting substrate and a second polarizing plate to the second light-transmitting substrate after irradiation of the liquid crystal layer with the ultraviolet light; and
fixing a backlight portion including plural kinds of light-emitting diodes so as to overlap with the pixel portion of the first light-transmitting substrate.

5. The manufacturing method of a semiconductor device according to claim 4, wherein the light-blocking layer overlaps with the oxide semiconductor layer.

6. The manufacturing method of a semiconductor device according to claim 4, wherein the liquid crystal layer includes a liquid crystal material exhibiting a blue phase.

7. The manufacturing method of a semiconductor device according to claim 4, wherein the liquid crystal layer includes a chiral agent.

8. A manufacturing method of a semiconductor device, comprising the steps of:
fixing a first light-transmitting substrate and a second light-transmitting substrate to each other with a liquid crystal layer including a photocurable resin and a photopolymerization initiator interposed therebetween; and
irradiating the liquid crystal layer with ultraviolet light from both above and below the first light-transmitting substrate and the second light-transmitting substrate.

9. The manufacturing method of a semiconductor device according to claim 8, wherein the liquid crystal layer includes a liquid crystal material exhibiting a blue phase.

10. The manufacturing method of a semiconductor device according to claim 8, wherein the liquid crystal layer includes a chiral agent.
